(19) United States
(12) Patent Application Publication
(10) Pub. No.: US 2024/0337928 A1
(43) Pub. Date: Oct. 10, 2024

(54) ORGANIC SALT, PHOTORESIST COMPOSITION INCLUDING THE SAME AND METHOD OF FORMING PATTERN BY USING THE PHOTORESIST PATTERN

(71) Applicant: Samsung Electronics Co., Ltd., Suwon-si (KR)

(72) Inventors: Hana KIM, Suwon-si (KR); Haengdeog KOH, Suwon-si (KR); Hyeran KIM, Suwon-si (KR); Youngmin NAM, Suwon-si (KR); Giyoung SONG, Hwaseong-si (KR); Changheon LEE, Suwon-si (KR); Aram JEON, Suwon-si (KR); Jungha CHAE, Suwon-si (KR); Songse YI, Hwaseong-si (KR); Sukkoo HONG, Hwaseong-si (KR)

(73) Assignee: Samsung Electronics Co., Ltd., Suwon-si (KR)

(21) Appl. No.: 18/613,810

(22) Filed: Mar. 22, 2024

(30) Foreign Application Priority Data
Mar. 24, 2023 (KR) 10-2023-0039250
May 8, 2023 (KR) 10-2023-0059416

(51) Int. Cl. G03F 7/004

(52) U.S. Cl. CPC G03F 7/0045

(57) ABSTRACT

Provided are an organic salt represented by Formula 1 below, a photoresist composition including the same, and a method of forming a pattern by using the photoresist composition.

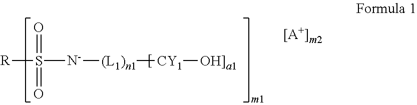

A description of Formula 1 is provided herein.

### CROSS-REFERENCE TO RELATED APPLICATION

This application is based on and claims priority under 35 U.S.C. § 119 to Korean Patent Application Nos. 10-2023-0039250, filed on Mar. 24, 2023, and 10-2023-0059416, filed on May 8, 2023 in the Korean Intellectual Property Office, the disclosures of each of which are incorporated by reference herein in their entireties.

### BACKGROUNDS

### 1. Field

The disclosure relates to an organic salt, a photoresist composition including the same, and a method of forming a pattern by using the photoresist composition.

### 2. Description of the Related Art

During manufacturing of semiconductors, photoresists of which physical properties change in response to light are being used to form fine patterns. Among the photoresists, chemically amplified photoresists have been widely used. In chemically amplified photoresists, acids formed when light reacts with photoacid generators react again with base resins to change the solubility of the base resins in developing solutions, thereby enabling patterning.

However, in the case of a chemically amplified resist, a formed acid may diffuse to an unexposed region, which may cause a problem such as a reduction in uniformity of patterns or an increase in surface roughness. Although quenchers are sometimes used to solve such problems, the use of quenchers has a problem in that the dose required for exposure may increase. Accordingly, there is a need for a quencher which has improved dispersibility and/or improved compatibility with a base resin and is capable of effectively acting even when a small amount is used.

### SUMMARY

Provided are an organic salt capable of serving as a quencher having improved dispersibility and/or compatibility, a photoresist composition including the same, and a method of forming a pattern by using the photoresist composition.

Additional aspects will be set forth in part in the description which follows and, in part, will be apparent from the description, or may be learned by practice of the presented embodiments of the disclosure.

According to an aspect of the disclosure, an organic salt is represented by Formula 1 below:

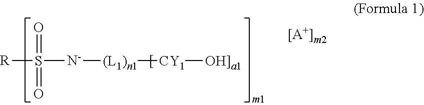

In Formula 1, L₁ may be a single bond or a (1+a1) valent linking group, wherein L₁ does not include a carbonyl group (C═O); n1 may be an integer from 1 to 5; CY₁ may be a cyclic C₁-C₂₀ divalent hydrocarbon group, which may optionally include a heteroatom, and may include two or more rings; a1 may be an integer from 1 to 5; R may be a linear, branched, or cyclic C₁-C₂₀ monovalent hydrocarbon group which may optionally include a heteroatom, a linear, branched, or cyclic C₁-C₂₀ divalent hydrocarbon group which may optionally include a heteroatom, or a linear, branched, or cyclic C₁-C₂₀ trivalent hydrocarbon group which may optionally include a heteroatom; m1 and m2 may each be an integer from 1 to 3; and A⁺ may be a counter cation.

According to another aspect of the disclosure, a photoresist composition includes the above-described organic salt, an organic solvent, and a base resin.

According to another aspect, a method of forming a pattern includes forming a resist film by applying the above-described photoresist composition, exposing at least a portion of the photoresist film to high-energy rays, and developing the exposed photoresist film using a developing solution.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment;

FIG. 2 shows side cross-sectional views illustrating a method of forming a pattern, according to an embodiment; and

FIG. 3 is a view illustrating a method of measuring an acid diffusion length (ADL) in Evaluation Example 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y. When the terms “about” are used in this specification in connection with a numerical value, it is intended that the associated numerical value includes a manufacturing tolerance (e.g., ±10%) around the stated numerical value. Further, regardless of whether values are modified as “about” or “substantially,” it will be understood that these values should be construed as including a manufacturing or operational tolerance (e.g., ±10%) around the stated values.

As used herein, “Cₓ-C_{y}” means that the number of carbon atoms constituting a substituent is in a range of x to y. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the valency of a “group” refers to the number of bonding sites the group, when viewed as a whole, includes. For example, the term “monovalent hydrocarbon group” represents a hydrocarbon group at the terminal position, and may include, for example, linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group), monovalent saturated cycloaliphatic hydrocarbon groups (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group), monovalent unsaturated aliphatic hydrocarbon groups (for example, an allyl group and a 3-cyclohexenyl), aryl groups (for example, a phenyl group, a 1-naphthyl group, and a 2-naphthyl group), arylalkyl groups (for example, a benzyl group and a diphenylmethyl group), and heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group). In addition, in these groups, some hydrogen atoms may be substituted by a moiety including a heteroatom such as oxygen, sulfur, nitrogen, or halogen, or some carbon atoms may be replaced by a moiety including a heteroatom such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety. Similarly, higher-order valence groups are represented by the number of bonding sites for the group, when viewed as a whole, such that divalent hydrocarbon groups, trivalent hydrocarbon groups, etc., each have, two, three, etc., binding sites to adjacent non-hydrogen atoms. Thereby, a divalent hydrocarbon group represents a linking group between two groups, a trivalent hydrocarbon group represents a linking group between three groups, etc.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and/or the like. As used herein, the term “alkylene group” refers to a linear or branched saturated aliphatic hydrocarbon divalent group, and specific examples thereof include a methylene group, an ethylene group, a propylene group, a butylene group, an isobutylene group, and/or the like.

As used herein, the term “halogenated alkyl group” refers to a group in which one or more substituents of an alkyl group are substituted with halogen, and specific examples thereof include CF₃ and/or the like. Here, a halogen is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and/or the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and/or the like.

As used herein, the term “cycloalkoxy group” refers to a monovalent group having a formula of —OA₁₀₂, wherein A₁₀₂ is a cycloalkyl group. Specific examples thereof include a cyclopropoxy group, a cyclobutoxy group, and/or the like.

As used herein, the term “heterocycloalkyl group” may be a group in which some carbon atoms of a cycloalkyl group are replaced by a moiety including a heteroatom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of a cycloalkylene group are replaced by a moiety including a heteroatom, for example, oxygen, sulfur, or nitrogen.

As used herein, the term “alkenylene group” refers to a linear or branched unsaturated aliphatic hydrocarbon divalent group.

As used herein, the term “cycloalkenylene group” refers to a divalent unsaturated hydrocarbon cyclic group.

As used herein, the term “heterocycloalkenylene group” is a group in which some carbon atoms of the cycloalkenylene group are replaced by a moiety including a heteroatom, for example, oxygen, sulfur, or nitrogen.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and/or the like. As used herein, the term “arylene group” refers to a divalent group having a carbocyclic aromatic system.

As used herein, the term “heteroaryl group” refers to a monovalent group having a heterocyclic aromatic system, and specific examples thereof include a pyridinyl group, a pyrimidinyl group, a pyrazinyl group, and/or the like. As used herein, the term “heteroarylene group” refers to a divalent group having a heterocyclic aromatic system.

As used herein, the term “cycloalkyl group” refers to a monovalent, divalent, or trivalent group in which any hydrogen of the cycloalkyl group may be optionally further replaced by a binding site.

As used herein, the term “heterocycloalkyl group” refers to a monovalent, divalent, or trivalent group in which any hydrogen of the heterocycloalkyl group may be optionally further replaced by a binding site.

As used herein, the term “cycloalkenyl group” refers to a monovalent, divalent, or trivalent group in which any hydrogen of the cycloalkenyl group may be further replaced by a binding site.

As used herein, the term “heterocycloalkenyl group” refers to a monovalent, divalent, or trivalent group in which any hydrogen of the heterocycloalkenyl group may be further replaced by a binding site.

As used herein, the term “aryl group” refers to a monovalent, divalent, or trivalent group in which any hydrogen of the aryl group may be further replaced by a binding site.

As used herein, the term “heteroaryl group” refers to a monovalent, divalent, or trivalent group in which any hydrogen of the heteroaryl group may be further replaced by a binding site.

As used herein, the term “counter cation” is any cation capable of ionic bonding with an anion and generally refers to a cation that prevents a compound from being charged.

Hereinafter, embodiments of the disclosure will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Organic Salt]

An organic salt according to embodiments may be represented by Formula 1 below:

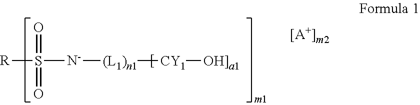

In Formula 1, L₁ may be a single bond, or a (1+a1) valent linking group, wherein L₁ does not include a carbonyl group (C═O); n1 may be an integer from 1 to 5; CY₁ may be a cyclic C₁-C₂₀ divalent hydrocarbon group, which may optionally include a heteroatom, and may include two or more rings; a1 may be an integer from 1 to 5; R may be a linear, branched, or cyclic C₁-C₂₀ monovalent hydrocarbon group which may optionally include a heteroatom, a linear, branched, or cyclic C₁-C₂₀ divalent hydrocarbon group which may optionally include a heteroatom, or a linear, branched, or cyclic C₁-C₂₀ trivalent hydrocarbon group which may optionally include a heteroatom; m1 and m2 may each be an integer from 1 to 3; and A⁺ may be a counter cation.

For example, in Formula 1, L₁ may be at least one of a single bond, sulfur (S), a linear, branched, or cyclic C₁-C₂₀ divalent hydrocarbon group, a linear, branched, or cyclic C₁-C₂₀ trivalent hydrocarbon group, a linear, branched, or cyclic C₁-C₂₀ tetravalent hydrocarbon group, a linear, branched, or cyclic C₁-C₂₀ pentavalent hydrocarbon group, or a linear, branched, or cyclic C₁-C₂₀ hexavalent hydrocarbon group.

For example, in Formula 1, L₁ may be a single bond or a C₁-C₂₀ alkylene group unsubstituted or substituted with at least one of deuterium, a halogen, a C₁-C₂₀ alkyl group, or any combination thereof.

In at least one embodiment, in Formula 1, CY₁ may be a C₃-C₂₀ cycloalkylene group, a C₁-C₂₀ heterocycloalkylene group, a C₆-C₂₀ arylene group, or a C₃-C₂₀ heteroarylene group, unsubstituted or substituted with at least one of deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or any combination thereof.

For example, in Formula 1, CY₁ may be a cyclohexylene group, a cycloheptenylene group, a cyclooctenylene group, an adamantylene group, a norbornylene group, a tricyclodecanylene group, or a tetracyclododecanylene group, unsubstituted or substituted with at least one of deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or any combination thereof.

More specifically, in Formula 1, CY₁ may be a cyclohexylene group, a cycloheptenylene group, a cyclooctenylene group, an adamantylene group, a norbornylene group, a tricyclodecanylene group, or a tetracyclododecanylene group, unsubstituted or substituted with at least one of —F, —Cl, —Br, —I, a hydroxyl group, a C₁-C₁₀ alkyl group, a cyclopentyl group, a cyclohexyl group, a phenyl group, a naphthyl group, or any combination thereof. In at least one embodiment, CY₁ may be, and/or include adamantane.

For example, in Formula 1, CY₁ may be selected from groups represented by Formulas CY1-3 to CY1-36 below, a group in which at least one hydrogen atom of one of the groups represented by Formulas CY1-3 to CY1-36 below is substituted with deuterium, a group in which at least one hydrogen atom of one of the groups represented by Formulas CY1-3 to CY1-36 is substituted with —F, a group in which at least one carbon atom of one of the groups represented by Formulas CY1-3 to CY1-36 below is substituted with oxygen, and/or a group in which at least one carbon atom of one of the groups represented by Formulas CY1-3 to CY1-36 below is substituted with a carbonyl group:

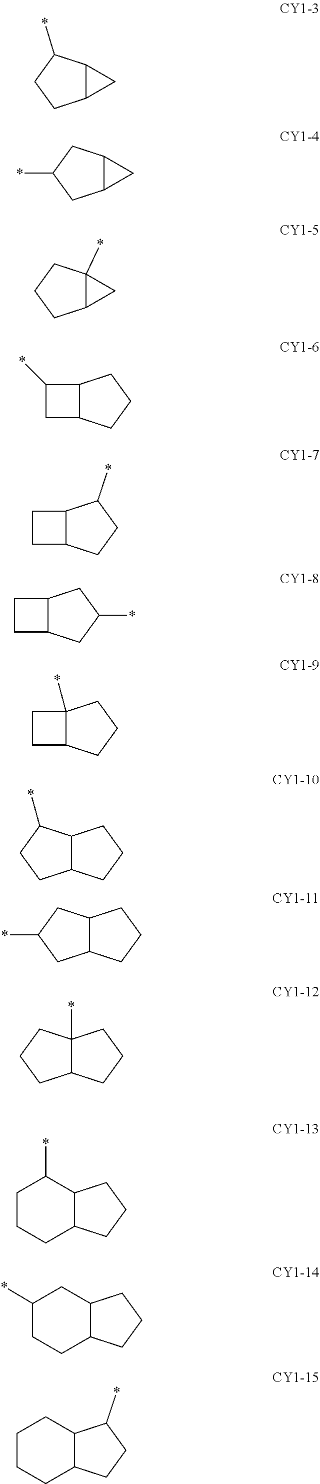

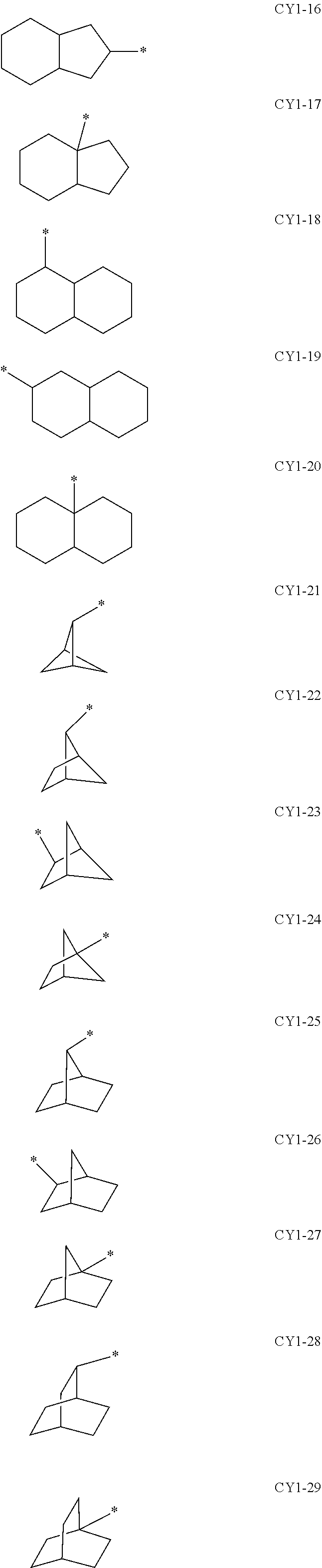

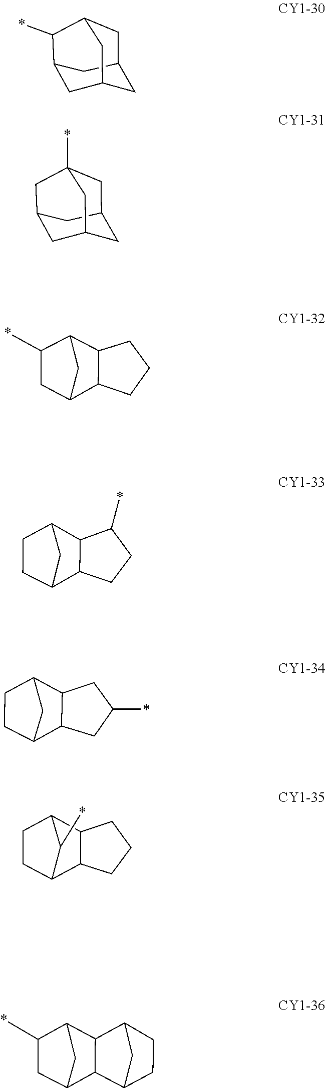

In Formulas CY1-3 to CY1-36, one hydrogen atom may be substituted with the hydroxyl group (—OH) in Formula 1, and * may be a binding site with adjacent L₁.

In at least one embodiment, in Formula 1, R may be a C₁-C₂₀ alkyl group, a C₃-C₂₀ cycloalkyl group, a C₁-C₂₀ heterocycloalkyl group, a C₆-C₂₀ aryl group, or a C₃-C₂₀ heteroaryl group, unsubstituted or substituted with at least one of deuterium, a halogen, a hydroxyl group, a C₁-C₂₀ alkyl group, a C₁-C₂₀ alkoxy group, a C₃-C₂₀ cycloalkyl group, a C₆-C₂₀ aryl group, a C₆-C₂₀ aryloxy group, a C₃-C₂₀ heteroaryl group, or any combination thereof.

Specifically, in Formula 1, R may be a C₁-C₁₀ alkyl group, a cyclohexyl group, a cycloheptenyl group, a cyclooctenyl group, an adamantyl group, a norbornyl group, a phenyl group, or a naphthyl group, unsubstituted or substituted with deuterium, a halogen, a hydroxyl group, a C₁-C₁₀ alkyl group, a C₁-C₁₀ alkoxy group, a C₃-C₁₀ cycloalkyl group, a C₆-C₂₀ aryl group, a C₆-C₂₀ aryloxy group, a C₃-C₂₀ heteroaryl group, or any combination thereof.

More specifically, in Formula 1, R may be a C₁-C₁₀ alkyl group, a cyclohexyl group, a cycloheptenyl group, a cyclooctenyl group, an adamantyl group, a norbornyl group, a phenyl group, or a naphthyl group, unsubstituted or substituted with —F, —Cl, —Br, —I, a hydroxyl group, a C₁-C₁₀ alkyl group, a C₁-C₁₀ alkoxy group, a cyclopentyl group, a cyclohexyl group, a phenyl group, a naphthyl group, a C₁-C₂₀ aryloxy group, or any combination thereof.

For example, R in Formula 1 may include at least one fluorine atom.

In at least one embodiment, in Formula 1, a1 may be 1 or 2.

In at least one embodiment, in Formula 1, m1 and m2 may be identical to each other.

In at least one embodiment, in Formula 1, i) a1 may be 1, and m1 and m2 may each be 1; and ii) a1 may be 1, and m1 and m2 may each be 2.

For example, the organic salt represented by Formula 1 may be represented by Formula 1-1 or Formula 1-2.

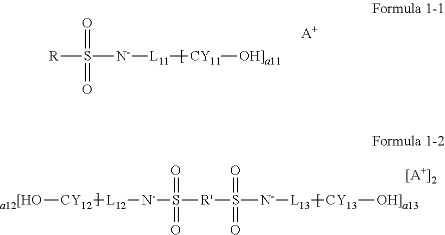

In Formula 1-1 and Formula 1-2, L₁₁ may be a single bond or a (1+a11) valent linking group, L₁₂ may be a single bond or a (1+a12) valent linking group, and/or L₁₃ may be a single bond or a (1+a13) valent linking group, wherein L₁₁ to L₁₃ each do not each include a carbonyl group (C═O); CY₁₁ to CY₁₃ may each independently be a cyclic C₁-C₂₀ divalent hydrocarbon group which may optionally include a heteroatom; a11 to a13 may each independently be an integer from 1 to 5; R may be a linear, branched, or cyclic C₁-C₂₀ monovalent hydrocarbon group which may optionally include a heteroatom; R′ may be a linear, branched, or cyclic C₁-C₂₀ divalent hydrocarbon group which may optionally include a heteroatom; and A⁺ may be a counter cation.

For example, in Formula 1-1 and Formula 1-2, L₁₁ to L₁₃ may each independently be a single bond, or a C₁-C₂₀ alkylene group unsubstituted or substituted with at least one of deuterium, a halogen, a C₁-C₂₀ alkyl group, or any combination thereof.

For example, in Formula 1-1 and Formula 1-2, CY₁₁ to CY₁₃ may each independently be a C₃-C₂₀ cycloalkylene group, a C₁-C₂₀ heterocycloalkylene group, a C₆-C₂₀ arylene group, or a C₃-C₂₀ heteroarylene group, unsubstituted or substituted with at least one of deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or any combination thereof.

In at least one embodiment, in Formula 1-1 and Formula 1-2, CY₁₁ to CY₁₃ may be a cyclohexylene group, a cycloheptenylene group, a cyclooctenylene group, an adamantylene group, a norbornylene group, a tricyclodecaneylene group, or a tetracyclododecanylene group, unsubstituted or substituted with at least one of deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or any combination thereof.

In at least one embodiment, in Formula 1-1 and Formula 1-2, CY₁₁ to CY₁₃ may be a cyclohexylene group, a cycloheptenylene group, a cyclooctenylene group, an adamantylene group, a norbornylene group, a tricyclodecaneylene group, or a tetracyclododecanylene group, unsubstituted or substituted with at least one of —F, —Cl, —Br, —I, a hydroxyl group, a C₁-C₁₀ alkyl group, a cyclopentyl group, a cyclohexyl group, a phenyl group, a naphthyl group, or any combination thereof.

In at least one embodiment, in Formula 1, A⁺ may be a substituted or unsubstituted sulfonium cation, a substituted or unsubstituted iodonium cation, a substituted or unsubstituted selenium cation, a substituted or unsubstituted tellurium cation, or any combination thereof.

For example, in Formula 1, A⁺ may be represented by at least one of Formulas 2-1 to 2-3 below:

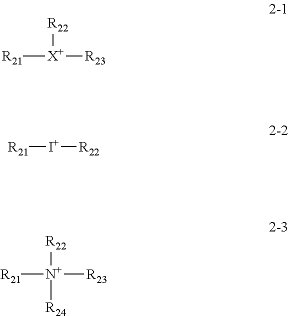

In Formulas 2-1 to 2-3, X⁺ may be S⁺, Se⁺, or Te⁺, R₂₁ to R₂₄ may each independently be a linear, branched, or cyclic C₁-C₃₀ monovalent hydrocarbon group which may optionally include a heteroatom, and adjacent two of R₂₁ to R₂₄ may be optionally bonded to each other to form a ring.

In at least one embodiment, in Formula 2-1, at least one of R₂₁ to R₂₃ may include one or more halogen atoms, in Formula 2-2, at least one of R₂₁ and R₂₂ may include one or more halogen atoms, and in Formula 2-3, at least one of R₂₁ to R₂₄ may include one or more halogen atoms.

For example, in Formula 2-1, at least one of R₂₁ to R₂₃ may be substituted with one or two halogen atoms, in Formula 2-2, at least one of R₂₁ and R₂₂ may be substituted with one or two halogen atoms, and in Formula 2-3, at least one of R₂₁ to R₂₄ may be substituted with one or two halogen atoms.

In at least one embodiment, in Formulas 2-1 to 2-3, R₂₁ to R₂₄ may be a C₁-C₁₀ alkyl group or a C₆-C₁₀ aryl group substituted with at least one halogen atom (for example, —F, —Cl, —Br, or —I).

In at least one embodiment, in Formula 1, A⁺ may be represented by one of Formulas 2-11 to 2-13 below:

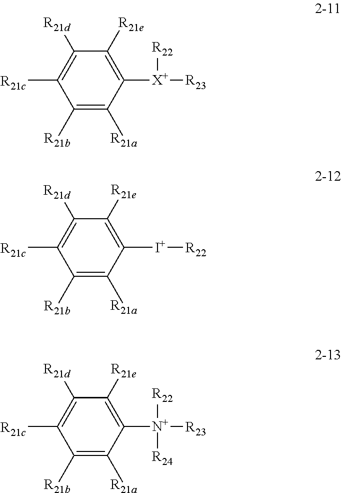

In Formulas 2-11 to 2-13, X⁺ may be S⁺, Se⁺, or Te⁺, R₂₁ₐ to R₂₁ₑ may each independently be hydrogen, deuterium, a halogen, a cyano group, a hydroxy group, or a linear, branched, or cyclic C₁-C₂₀ monovalent hydrocarbon group which may optionally include a heteroatom, R₂₂ to R₂₄ may each independently be a linear, branched, or cyclic C₁-C₃₀ monovalent hydrocarbon group which may optionally include a heteroatom, and adjacent two of R₂₁ₐ to R₂₁ₑ and R₂₂ to R₂₄ may be optionally bonded to each other to form a ring.

For example, in Formulas 2-11 to 2-13, at least one of R₂₁ₐ to R₂₁ₑ may be a halogen atom (for example, —F, —Cl, —Br, or —I), or a C₁-C₁₀ alkyl group substituted with at least one halogen atom.

In at least one embodiment, in Formula 1, A⁺ may be represented by at least one of Formulas 2-21 to 2-23 below:

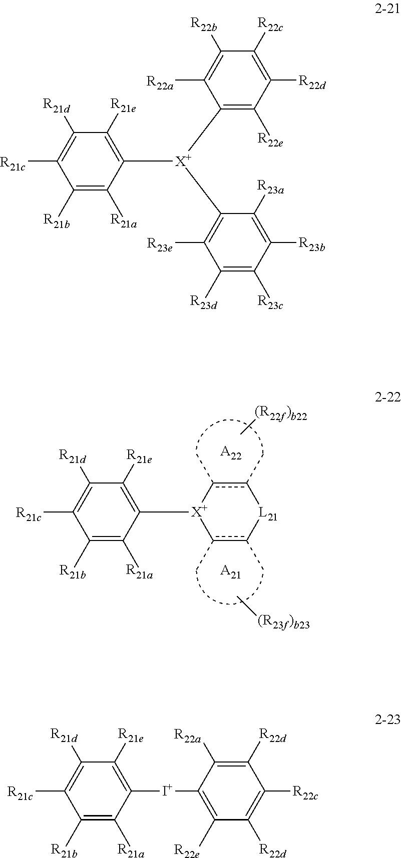

In Formulas 2-21 to 2-23, X⁺ may be S⁺, Se⁺, or Te⁺; R₂₁ₐ to R₂₁ₑ, R₂₂ₐ to R_{22f}, and R₂₃ₐ to R_{23f} may each independently be at least one hydrogen, deuterium, a halogen, a cyano group, a hydroxy group, or a linear, branched, or cyclic C₁-C₂₀ monovalent hydrocarbon group which may optionally include a heteroatom; adjacent two of R₂₁ₐ to R₂₁ₑ, R₂₂ₐ to R_{22f}, and R₂₃ₐ to R_{23f} may be optionally bonded to each other to form a ring, b22 and b23 may each be an integer from 1 to 4; A₂₁ and A₂₂ may each independently be absent or a benzene ring, [symbol] may each be a carbon-carbon single bond or a carbon-carbon double bond, L₂₁ may be a single bond, O, S, CO, SO, SO₂, CRₐR_{b}, or NR_{b}; and Rₐ and R_{b} may each independently be at least one of hydrogen, deuterium, a halogen, a cyano group, a hydroxy group, or a linear, branched, or cyclic C₁-C₂₀ monovalent hydrocarbon group which may optionally include a heteroatom.

For example, in Formulas 2-21 to 2-23, at least one of R₂₁ₐ to R₂₁ₑ, R₂₂ₐ to R_{22f}, and R₂₃ₐ to R_{23f} may be a halogen atom (for example, —F, —Cl, —Br, or —I, etc.), or a C₁-C₁₀ alkyl group substituted with at least one halogen atom.

In at least one embodiment, in Formula 1, A⁺ may be selected from Group I below:

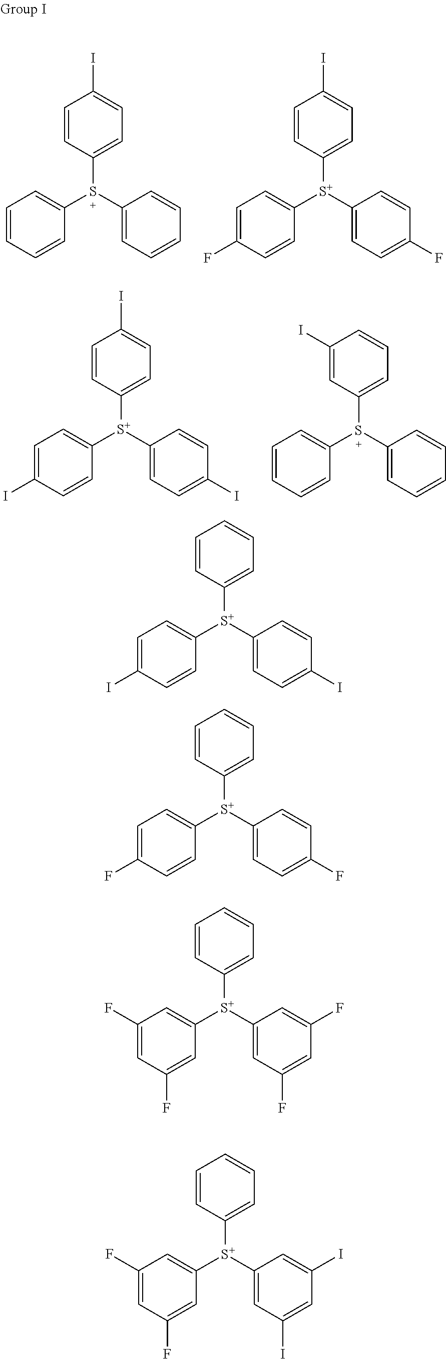

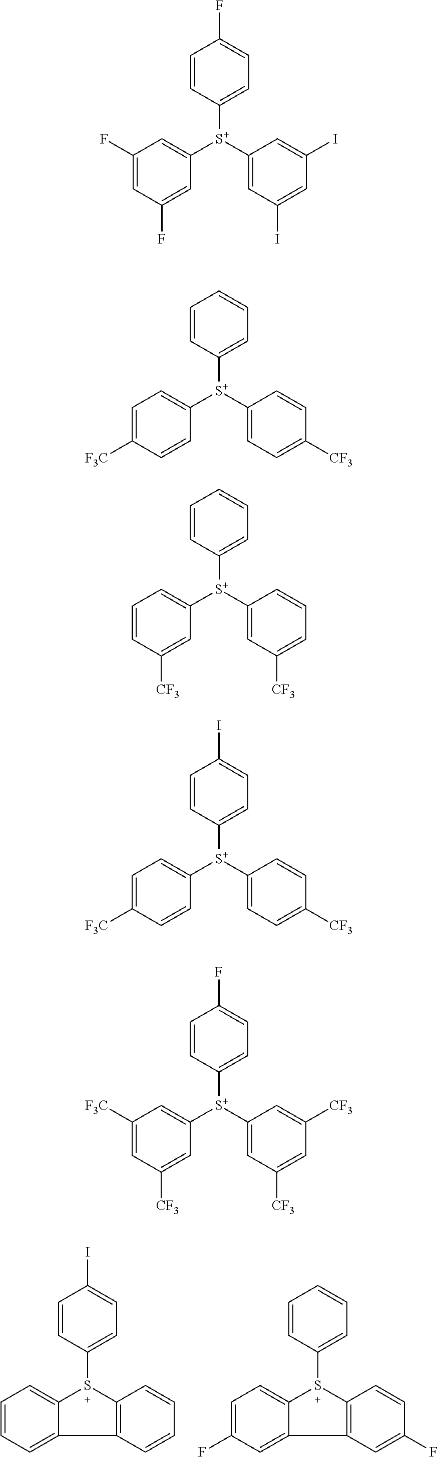

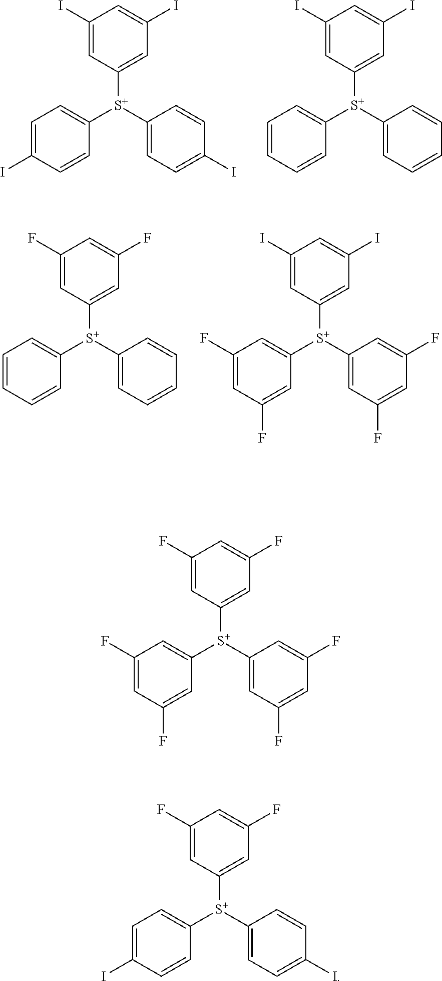 [SMILES: Ic1ccc([S+](c2ccc(I)cc2)c2cc(I)cc(I)c2)cc1 ; Ic1cc(I)cc([S+](c2ccccc2)c2ccccc2)c1 ; Fc1cc(F)cc([S+](c2ccccc2)c2ccccc2)c1 ; Fc1cc(F)cc([S+](c2cc(F)cc(F)c2)c2cc(I)cc(I)c2)c1 ; Fc1cc(F)cc([S+](c2cc(F)cc(F)c2)c2cc(F)cc(F)c2)c1 ; Fc1cc(F)cc([S+](c2ccc(I)cc2)c2ccc(I)cc2)c1]

In at least one embodiment, the organic salt represented by Formula 1 may be selected from Group II below:

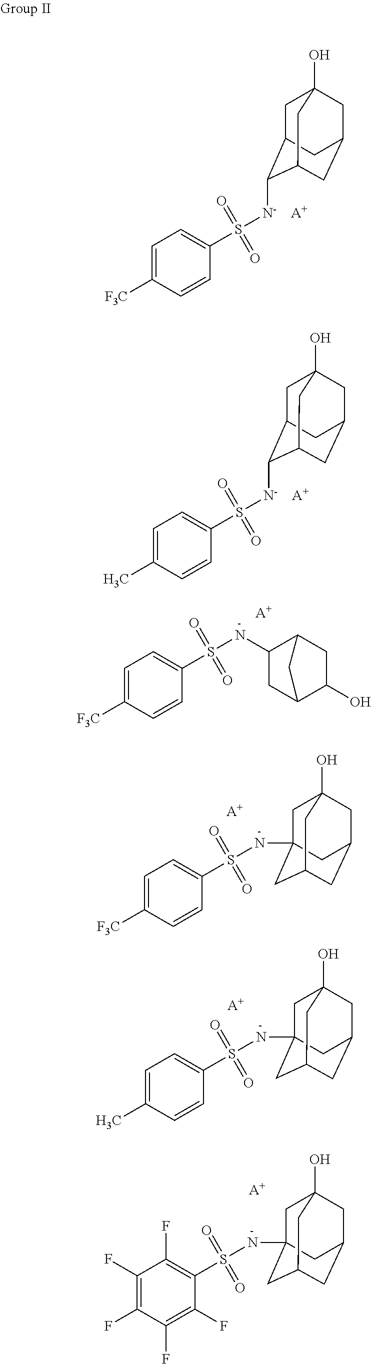

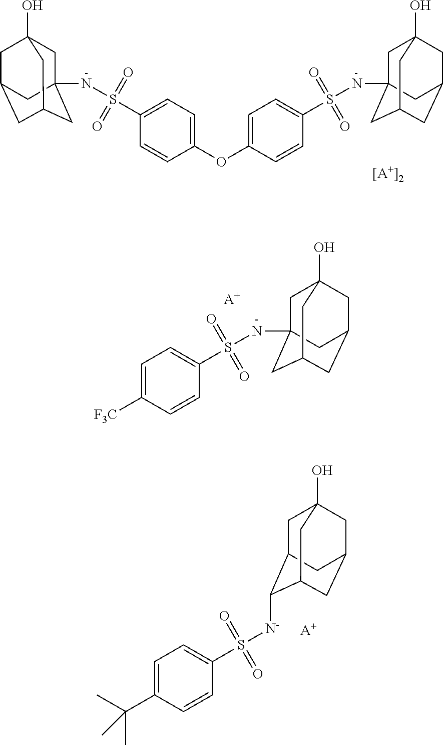

In Group II, A⁺ may be a counter cation, as described above.

For example, in Group II, A⁺ may be selected from Group I.

Typically, when a pattern is formed using a photoresist composition, acids generated from a photoacid generator by exposure may diffuse into the photoresist film. As a result, acids may penetrate into an unexposed region, and thus sensitivity and/or resolution may be lowered. Therefore, in order to improve the sensitivity and/or resolution of a photoresist composition, acid diffusion has to be effectively reduced, and a quencher may be used for this purpose.

However, simply using a quencher may not reduce acid diffusion if, e.g., the quencher is not properly dispersed and/or is not compatible with the base resin. Therefore, in order to increase an effect of the quencher while using an appropriate amount of the quencher, it is necessary to improve the dispersibility of the quencher and/or compatibility with a base resin.

In particular, in order to improve compatibility with a base resin, a method of coupling macromolecules has been studied. However, through such methods, problems-such as reduced solubility of a quencher in an organic solvent and/or reduced compatibility with the base resin-could not be solved. In addition, in order to improve compatibility with a base resin, a method of binding a quencher to the base resin itself has been studied. However, the method has been very difficult to actually apply due to problems such as a reduction in solubility of the base resin itself and/or an effect on contrast caused by a quencher.

In addition, typically, when a low-molecular-weight quencher is used, aggregation occurs in a base resin due to interactions between low-molecular-weight quencher molecules (particularly, interactions due to an electrostatic attractive force acting between ion-binding molecules), and there has been a problem that acid diffusion may not be effectively reduced when a small amount of quencher is applied.

However, a hydroxyl group (—OH) may be introduced into the organic salt represented by Chemical Formula 1, thereby suppressing the dispersion of a photodegradable compound in a photoresist composition, and reducing an effective acid diffusion length (ADL) to contribute to improving pattern performance.

### [Photoresist Composition]

According to another aspect, there may be provided a photoresist composition including the above-described organic salt, an organic solvent, and a base resin. The photoresist composition may have properties such as improved developability and/or improved resolution. In at least one embodiment, the photoresist composition may further include a quencher.

The solubility of the photoresist composition in a developing solution may be changed by exposure to high-energy rays (such as ultraviolet (UV) rays, deep UV (DUV) rays, electron beams (EBs), extreme ultraviolet (EUV) rays, X-rays, α-rays, γ-rays, and/or the like). The photoresist composition may be a positive photoresist composition in which an exposed portion of a photoresist film is dissolved and removed to form a positive photoresist pattern, or a negative photoresist composition in which an unexposed portion of a photoresist film is dissolved and removed to form a negative photoresist pattern. In addition, a sensitive photoresist composition according to an embodiment may be for an alkali developing process in which an alkali developing solution is used for a developing process when a photoresist pattern is formed and may also be for a solvent developing process in which an organic solvent-containing developing solution (hereinafter referred to as an organic developing solution) is used for the developing process.

The organic salt may generate an acid upon exposure and may be a photodegradable compound that serves as a quenching base configured to neutralize acids before exposure. In this case, the organic salt may be used in combination with a photoacid generator that generates acids. In addition, since the organic salt may generate an acid upon exposure to the high-energy rays, the organic salt may be neutralized with the acid generated by the organic solvent to lose a quencher function, and thus a contrast between an exposed portion and an unexposed portion may be further enhanced.

The organic salt may be used in a range of about 0.1 parts by weight to about 40 parts by weight; for example, about 5 parts by weight to about 30 parts by weight, with respect to about 100 parts by weight of the base resin. When the above range is satisfied, a quencher function may be exhibited at an appropriate level, and the formation of foreign particles due to any performance loss, for example, a decrease in sensitivity and/or lack of solubility, may be reduced.

Since the organic salt is as described above, the organic solvent, the base resin, and any components such as a photoacid generator contained as necessary will be described below. In addition, as the organic salt used in the photoresist composition and represented by Formula 1, one type of an organic salt may be used, or two or more different types of organic salts may be used in combination.

### <Organic Solvent>

An organic solvent included in the photoresist composition is not particularly limited as long as the organic solvent is capable of dissolving or dispersing an organic salt, a base resin, a photoacid generator, and any additional components contained. As the organic solvent, one type of an organic solvent may be used, and/or two or more different types of organic solvents may be used in combination. In addition, a mixed solvent in which water and an organic solvent are mixed may be used.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and/or the like.

More specifically, examples of the alcohol-based solvent may include a monoalcohol-based solvent (such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonylalcohol, 2,6-dimethyl-4-heptaneol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, diacetone alcohol and/or the like), a polyhydric alcohol-based (solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol and/or the like), and/or a polyhydric alcohol-containing ether-based solvent (such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether, propylene glycol dimethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether and/or the like). However, the examples are not limited thereto.

Examples of the ether-based solvent may include a polyhydric alcohol-containing ether-based solvent, a dialkyl ether-based solvent (such as diethyl ether, dipropyl ether, dibutyl ether polyhydric alcohol-containing ether-based solvent, a cyclic ether-based solvent (such as tetrahydrofuran, tetrahydropyran polyhydric alcohol-containing ether-based solvent), and/or an aromatic ring-containing ether-based solvent (such as diphenyl ether, anisole polyhydric alcohol-containing ether-based solvent. However, the examples are not limited thereto.

Examples of the ketone-based solvent may include a chain ketone-based solvent (such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, trimethylnonanone, and/or the like), a cyclic ketone-based solvent (such as cyclopentanone, cyclohexanone, cycloheptanone, cyclooctanone, methylcyclohexanone, and/or the like), 2,4-pentanedione, acetonyl acetone, and acetophenone. However, the examples are not limited thereto.

Examples of the amide-based solvent may include a cyclic amide-based solvent (such as N,N′-dimethylimidazolidinone, N-methyl-2-pyrrolidone, and/or the like), and/or a chain amide-based solvent (such as N-methylformamide, N,N-dimethylformamide, N,N-diethylformamide, acetamide, N-methylacetamide, N,N-dimethylacetamide, N-methylpropionamide, and/or the like). However, the examples are not limited thereto.

Examples of the ester-based solvent may include an acetate ester-based solvent (such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and/or the like), a polyhydric alcohol-containing ether carboxylate-based solvent (such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and/or the like), a lactone-based solvent (such as 7-butyrolactone, 6-valerolactone, and/or the like), a carbonate-based solvent (such as dimethyl carbonate, diethyl carbonate, ethylene carbonate, or propylene carbonate, a lactate ester-based solvent such as methyl lactate, ethyl lactate, n-butyl lactate, n-amyl lactate, and/or the like), glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and/or diethyl phthalate. However, the examples are not limited thereto.

Examples of the sulfoxide-based solvent may include dimethyl sulfoxide, and/or diethyl sulfoxide. However, the examples are not limited thereto.

Examples of the hydrocarbon-based solvent may include an aliphatic hydrocarbon-based solvent (such as n-pentane, isopentane, n-hexane, isohexane, n-heptane, isoheptane, 2,2,4-trimethylpentane, n-octane, isooctane, cyclohexane, methylcyclohexane, and/or the like), and/or an aromatic hydrocarbon-based solvent (such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, n-amylnaphthalene, and/or the like). However, the examples are not limited thereto.

In at least one embodiment, the organic solvent may be selected from an alcohol-based solvent, an amide-based solvent, an ester-based solvent, a sulfoxide-based solvent, and/or any combination thereof. For example, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combination thereof.

Meanwhile, when an acid labile group in the form of acetal is used, in order to accelerate a deprotection reaction of acetal, high-boiling alcohol such as diethylene glycol, propylene glycol, glycerol, 1,4-butanediol, or 1,3-butanediol may be further added to the organic solvent.

In at least one embodiment, the organic solvent may be used in a range of about 200 parts by weight to about 5,000 parts by weight, specifically, about 400 parts by weight to about 3,000 parts by weight, with respect to about 100 parts by weight of the base resin.

### <Base Resin>

The base resin may include a repeating unit including an acid labile group represented by, e.g., Formula 4 below:

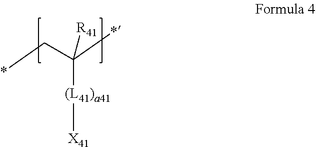

In Formula 4, R₄₁ may be hydrogen, deuterium, a halogen, a linear or branched C₁-C₂₀ alkyl group, or a linear or branched C₁-C₂₀ halogenated alkyl group, L₄₁ may be a single bond, O, C(═O), C(═O)O, OC(═O), C(═O)NH, NHC(═O), a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, a substituted or unsubstituted C₁-C₃₀ heteroarylene group, or any combination thereof, a41 may be an integer from 1 to 6, X₄₁ may be an acid labile group, * and *′ may each be a binding site with an adjacent atom. In at least one embodiment, the substituted C₁-C₃₀ alkylene group, substituted C₃-C₃₀ cycloalkylene group, substituted C₃-C₃₀ heterocycloalkylene group, substituted C₂-C₃₀ alkenylene group, substituted C₃-C₃₀ cycloalkenylene group, substituted C₃-C₃₀ heterocycloalkenylene group, substituted C₆-C₃₀ arylene group, or substituted C₁-C₃₀ heteroarylene group substituent may include at least one of deuterium, —F, —Cl, —Br, —I, —CD₃, —CD₂H, —CDH₂, —CF₃, —CF₂H, —CFH₂, a hydroxyl group, a carboxylic acid group or a salt thereof, a sulfonate group or a salt thereof, a phosphoric acid group or a salt thereof, a C₁-C₂₀ alkyl group, a C₂-C₂₀ alkenyl group, a C₂-C₂₀ alkynyl group, or a C₁-C₂₀ alkoxy group; a C₁-C₂₀ alkyl group, a C₂-C₂₀ alkenyl group, a C₂-C₂₀ alkynyl group, or a C₁-C₂₀ alkoxy group, substituted with deuterium, —F, —Cl, —Br, —I, —CD₃, —CD₂H, —CDH₂, —CF₃, —CF₂H, —CFH₂, a hydroxyl group, a carboxylic acid group or a salt thereof, a sulfonate group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, a monovalent non-aromatic condensed polycyclic group, a monovalent non-aromatic hetero condensed polycyclic group, or any combination thereof; a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, a monovalent non-aromatic condensed polycyclic group, or monovalent non-aromatic hetero condensed polycyclic group; or a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₂₀ aryl group, a C₆-C₂₀ aryloxy group, a C₆-C₂₀ arylthio group, a C₁-C₂₀ heteroaryl group, a monovalent non-aromatic condensed polycyclic group, or a monovalent non-aromatic condensed heteropolycyclic group, substituted with deuterium, —F, —Cl, —Br, —I, —CD₃, —CD₂H, —CDH₂, —CF₃, —CF₂H, —CFH₂, a hydroxyl group, a carboxylic acid group or a salt thereof, a sulfonate group or a salt thereof, a phosphoric acid group or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₂₀ aryl group, a C₆-C₂₀ aryloxy group, a C₆-C₂₀ arylthio group, a C₁-C₆₀ heteroaryl group, a C₁-C₂₀ heteroaryloxy group, a C₁-C₂₀ a heteroarylthio group, a monovalent non-aromatic condensed polycyclic group, a monovalent non-aromatic hetero condensed polycyclic group, or any combination thereof.

For example, in Formula 4, R₄₁ may be hydrogen, deuterium, a halogen, CH₃, CH₂F, CHF₂, or CF₃.

In Formula 4, examples of a “C₁-C₁₀ alkylene group” of L₄₁ may include a methylene group, an ethylene group, a propylene group, a butylene group, an isobutylene group, and/or the like.

In Formula 4, examples of a “C₃-C₁₀ cycloalkylene group” of L₄₁ may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and/or the like.

In Formula 4, a “C₁-C₁₀ heterocycloalkylene group” of L₄₁ may be a group in which some carbon atoms of the “C₃-C₁₀ cycloalkylene group” are replaced with a moiety including a heteroatom, for example, oxygen, sulfur, or nitrogen, and thus the “C₁-C₁₀ heterocycloalkylene group” may include an ether bond, an ester bond, a sulfonate ester bond, carbonate, a lactone ring, a sultone ring, a carboxylic anhydride moiety, and/or the like.

In Formula 4, a41 may refer to the number of repetitions of L₄₁, and when a41 is 2 or more, a plurality of L₄₁s may be identical to or different from each other.

In at least one embodiment, in Formula 4, X₄₁ may be represented by one of Formulas 6-1 to 6-7 below:

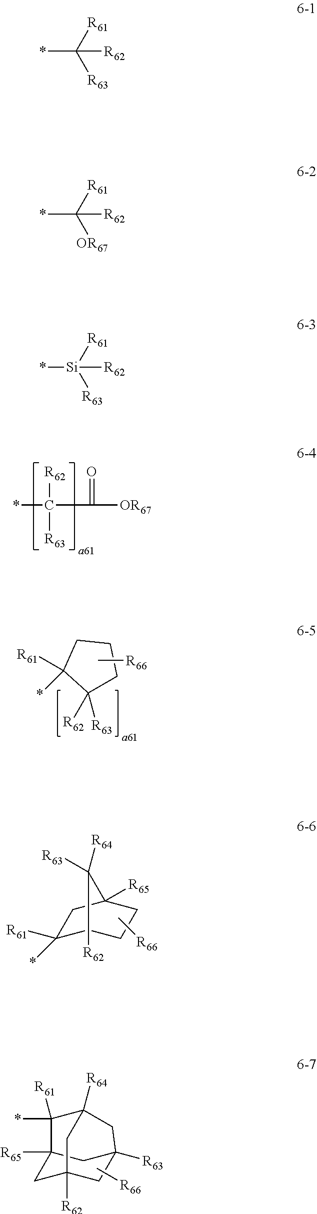

In Formulas 6-1 to 6-7, a61 may be an integer from 0 to 6, R₆₁ to R₆₆ may each independently be selected from hydrogen, deuterium, a halogen, a cyano group, a hydroxyl group, an amino group, a carboxylic acid group, and a linear, branched, or cyclic C₁-C₂₀ monovalent hydrocarbon group which may optionally include a heteroatom, R₆₇ may be a linear, branched, or cyclic C₁-C₂₀ monovalent hydrocarbon group which may optionally include a heteroatom, two adjacent groups of R₆₁ to R₆₇ may be optionally bonded to each other to form a ring, and * may be a binding site with an adjacent atom.

In Formula 6-4 and Formula 6-5, when a61 is 0, (CR₆₂R₆₃)ₐ₆₁ may be a single bond.

In Formula 6-1 to Formula 6-7, the “monovalent hydrocarbon group” of R₆₁ to R₆₇ may be understood with reference to the “monovalent hydrocarbon group” in the list of R in Formula 1.

In at least one embodiment, the repeating unit represented by Formula 4 may be represented by one of Formula 4-1 and Formula 4-2 below:

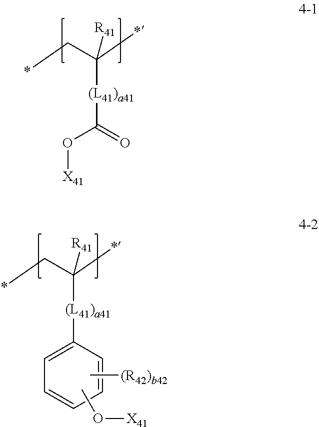

In Formulas 4-1 and 4-2, The definitions of L₄₁ and X₄₁ may each be the same as those in Formula 4, a41 may be an integer from 1 to 4, R₄₂ may be hydrogen or a linear, branched, or cyclic C₁-C₁₀ monovalent hydrocarbon group which may optionally include a hetero atom, b42 may be an integer from 1 to 4, and * and *′ may each be a binding site with an adjacent atom.

In Formula 4-2, a “monovalent hydrocarbon group” of R₄₂ may be understood with reference to the “monovalent hydrocarbon group in the list of R₁₁ in Formula 1.

The base resin including the repeating unit represented by Formula 4 may be decomposed under the action of an acid to generate a carboxyl group, thereby being converted to be alkali soluble.

In addition to the repeating unit represented by Formula 4, the base resin may further include a repeating unit represented by Formula 5 below:

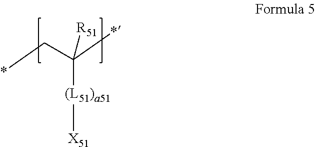

In Formula 5, R₅₁ may be hydrogen, deuterium, a halogen, a linear or branched C₁-C₂₀ alkyl group, or a linear or branched C₁-C₂₀ halogenated alkyl group, L₅₁ may be a single bond, O, C(═O), C(═O)O, OC(═O), C(═O)NH, NHC(═O), a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, a substituted or unsubstituted C₁-C₃₀ heteroarylene group, or any combination thereof, a51 may be an integer from 1 to 6, X₅₁ may be a non-acid labile group, * and *′ may each be a binding site with an adjacent atom, and the substituted C₁-C₃₀ alkylene group, substituted C₃-C₃₀ cycloalkylene group, substituted C₃-C₃₀ heterocycloalkylene group, substituted C₂-C₃₀ alkenylene group, substituted C₃-C₃₀ cycloalkenylene group, substituted C₃-C₃₀ heterocycloalkenylene group, substituted C₆-C₃₀ arylene group, or substituted C₁-C₃₀ heteroarylene group substituent may be the same as those described in Formula 4. Thereby, in at least some embodiments, the base resin may include, for example, a copolymer of Formula 4 (including the X₄₁ acid labile group) and Formula 5 (including the X₅₁ non-acid labile group).

For example, in Formula 5, R₅₁ may be understood with reference to the description of R₄₁ in Formula 4.

In Formula 5, L₅₁ may be understood with reference to the description of L₄₁ in Formula 4.

In Formula 5, a51 may refer to the number of repetitions of L₅₁, and when a51 is 2 or more, a plurality of L₅₁s may be identical to or different from each other.

In at least one embodiment, in Formula 5, X₅₁ may be hydrogen, or a linear, branched, or cyclic C₁-C₂₀ monovalent hydrocarbon group including at least one polar moiety selected from a hydroxyl group, a halogen, a cyano group, a carbonyl group, a carboxyl group, *—O—*′, *—C(═O)O—*′, —OC(═O)—*′, *—S(═O)O—*′, —OS(═O)—*′, a lactone ring, a sultone ring, and an carboxylic anhydride moiety. Here, the “monovalent hydrocarbon group” may be understood with reference the “monovalent hydrocarbon group” in the list of R₁₁ in Formula 1 and may necessarily include at least one polar moiety selected from a hydroxy group, a halogen, a cyano group, a carbonyl group, a carboxyl group, *—O—*′, *—C(═O)O—*′, —OC(═O)—*′, *—S(═O)O—*′, —OS(═O)—*′, a lactone ring, a sultone ring, and a carboxylic anhydride moiety.

In at least one embodiment, the repeating unit represented by Formula 5 may be represented by one of Formula 5-1 and Formula 5-2.

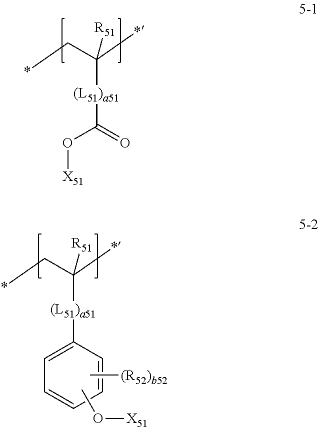

In Formula 5-1 and Formula 5-2, the definitions of L₅₁ and X₅₁ may each be the same as those in Formula 5, a51 may be an integer from 1 to 4, R₅₂ may be hydrogen, a hydroxy group, or a linear, branched, or cyclic C₁-C₁₀ monovalent hydrocarbon group which may optionally include a heteroatom, b52 may be an integer from 1 to 4, and * and *′ may each be a binding site with an adjacent atom.

In Formula 5-2, the “monovalent hydrocarbon group of R₅₂ may be understood with reference to the “monovalent hydrocarbon group in the list of R₁₁ in Formula 1.

For example, in an Argon-Fluoride (ArF) lithography process, X₅₁ may include a lactone ring as a polar moiety, and in Krypton-Fluoride (KrF), electron beam (EB), and extreme ultraviolet (EUV) lithography processes, X₅₁ may be phenol.

In at least one embodiment, the base resin may further include a moiety including an anion and/or a cation. For example, the base resin may further include a moiety in which a photoacid generator and/or a quencher are derived to bind to a side chain.

In at least some embodiments, the base resin may have a weight average molecular weight Mw of about 1,000 to about 500,000, specifically, about 3,000 to about 100,000, when measured, e.g., through gel permeation chromatography using, e.g., a tetrahydrofuran solvent and polystyrene as standard materials.

A polydispersity index (PDI: Mw/Mn) of the base resin may be in a range of about 1.0 to about 3.0, specifically, about 1.0 to about 2.0. When the above range is satisfied, a possibility of foreign materials remaining on a pattern may be lowered, or the deterioration of a pattern profile may be minimized. Accordingly, the photoresist composition may be more suitable for forming a fine pattern.

The base resin may be prepared through any suitable method and may be prepared, for example, by dissolving unsaturated bond-containing monomer(s) in an organic solvent, and then heat-polymerizing the unsaturated bond-containing monomer(s) in a radical initiator.

In the base resin, a mole fraction (mol %) of each repeating unit derived from each monomer may be as follows (but one or more embodiments are not limited thereto): i) the base resin includes the repeating unit represented by Formula 4 in a range of about 1 mol % to about 60 mol %, specifically, about 5 mol % to about 50 mol %, or more specifically, about 10 mol % to about 50 mol %, and/or ii) the repeating unit represented by Formula 5 in a range of about 40 mol % to about 99 mol %, specifically, about 50 mol % to about 95 mol %, or more specifically, about 50 mol % to about 90 mol %.

The base resin may be a single polymer or may include a mixture of two or more types of polymers having different compositions, weight average molecular weights, and/or polydispersity indices.

### <Photoacid Generator>

When the organic salt represented by Formula 1 serves as a quencher, the organic solvent may be used in combination with a photoacid generator that generates an acid.

The photoacid generator may be a compound configured to generate an acid when exposed to high-energy rays such as UV rays, DUV rays, EBs, EUV rays, X-rays, α-rays, γ-rays, and/or the like.

In at least one embodiment, the photoacid generator may include at least one of a sulfonium salt, an iodonium salt, and a combination thereof. However, the embodiments are not limited thereto.

In at least one embodiment, the photoacid generator may be represented by Formula 7.

B₇₁⁺A₇₁⁻ Formula 7

In Formula 7, B₇₁⁺ may be represented by Formula 7A below, A₇₁⁻ may be represented by one of Formulas 7B to 7D below, and B₇₁⁺ and A₇₁⁻ may be optionally linked through a covalent bond.

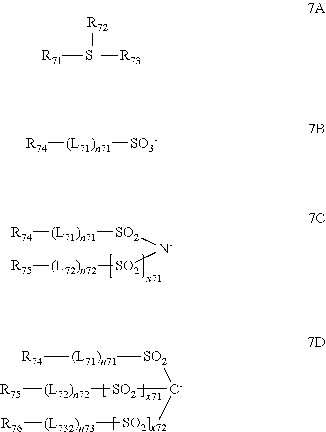

In Formulas 7A to 7D, L₇₁ to L₇₃ may each independently be a single bond or CRR′, R and R′ may each independently be hydrogen, deuterium, a halogen, a cyano group, a hydroxyl group, a C₁-C₂₀ alkyl group, a C₁-C₂₀ halogenated alkyl group, a C₁-C₂₀ alkoxy group, a C₃-C₂₀ cycloalkyl group, or a C₃-C₂₀ cycloalkoxy group; n71 to n73 may each independently be 1, 2, or 3; x71 and x72 may each independently be 0 or 1; R₇₁ to R₇₃ may each independently be a linear, branched, or cyclic C₁-C₂₀ monovalent hydrocarbon group, adjacent two of R₇₁ to R₇₃ may be optionally bonded to each other to form a ring, and R₇₄ to R₇₆ may each independently be hydrogen, a halogen, or a linear, branched, or cyclic C₁-C₂₀ monovalent hydrocarbon group which may optionally include a heteroatom.

In at least one embodiment, in Formula 7, B₇₁⁺ may be represented by Formula 7A, and A₇₁⁻ may be represented by Formula 7B. In at least one embodiment, in Formula 7A, R₇₁ to R₇₃ may each be a phenyl group.

The photoacid generator may be included in a range of 0 parts by weight to about 40 parts by weight, about 0.1 parts by weight to about 40 parts by weight, or about 0.1 parts by weight to about 20 parts by weight with respect to about 100 parts by weight of the base resin. When the above range is satisfied, appropriate resolution may be achieved, and problems related to foreign material particles after development or during stripping may be reduced.

As the photoacid generator, one type of a photoacid generator may be used, or two or more different types of photoacid generators may be mixed and used.

### <Quencher>

The quencher may include a salt that generates an acid having weaker acidity than an acid generated from the organic salt represented by Formula 1 and/or the photoacid generator.

The quencher may include at least one of an ammonium salt, a sulfonium salt, an iodonium salt, and a combination thereof.

In at least one embodiment, the quencher may be represented by Formula 8 below:

B₈₁⁺A₈₁⁻ Formula 8

In Formula 8, B₈₁⁺ may be represented by one of Formulas 8A to 8C below, A₈₁⁻ may be represented by one of Formulas 8D to 8F below, and B₈₁⁺ and A₈₁⁻ may be optionally linked through a covalent bond.

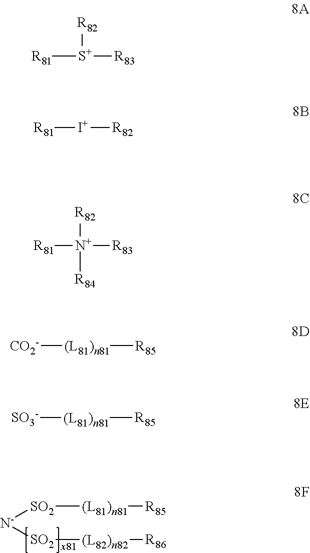

In Formulas 8A to 8F, L₈₁ and L₈₂ may each independently be a single bond or CRR′, R and R′ may each independently be hydrogen, deuterium, a halogen, a cyano group, a hydroxyl group, a C₁-C₂₀ alkyl group, a C₁-C₂₀ halogenated alkyl group, a C₁-C₂₀ alkoxy group, a C₃-C₂₀ cycloalkyl group, or a C₃-C₂₀ cycloalkoxy group, n81 and n82 may each independently be 1, 2, or 3, x81 may be 0 or 1, R₈₁ to R₈₄ may each independently be a linear, branched, or cyclic C₁-C₂₀ monovalent hydrocarbon group, adjacent two of R₈₁ to R₈₄ may be optionally bonded to each other to form a ring, and R₈₅ and R₈₆ may each be hydrogen, a halogen, or a linear, branched, or cyclic C₁-C₂₀ monovalent hydrocarbon group which may optionally include a heteroatom.

The quencher may be included in a range of about 0.01 parts by weight to about 10 parts by weight, about 0.05 parts by weight to about 5 parts by weight, or about 0.1 parts by weight to about 3 parts by weight with respect to about 100 parts by weight of the base resin. When the above range is satisfied, appropriate resolution may be achieved, and problems related to foreign material particles after development or during stripping may be reduced.

As the quencher, one type of a quencher may be used, or two or more different types of quenchers may be mixed and used.

### <Any Components>

In at least some embodiments, the photoresist composition may further include a surfactant, a crosslinking agent, a leveling agent, a colorant, or any combination thereof as necessary.

For example, the photoresist composition may further include a surfactant to improve coatability, developability, and/or the like. Examples of the surfactant may include, for example, a nonionic surfactant (such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, and/or the like). As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included in a range of 0 parts by weight to about 20 parts by weight with respect to about 100 parts by weight of the base resin. For example, in at least some embodiments, about 0.1 parts by weight to about 20 parts by weight with respect to about 100 parts by weight of the base resin. As the surfactant, one type of a surfactant may be used, or two or more different types of surfactants may be mixed and used.

A method of preparing the photoresist composition is not particularly limited, and for example, a method of mixing the organic salt represented by Formula 1, a base resin, a photoacid generator, and any components added as necessary in an organic solvent may be used. A temperature or time during mixing is not particularly limited. If necessary, filtration may be performed after mixing.

### [Method of Forming Pattern]

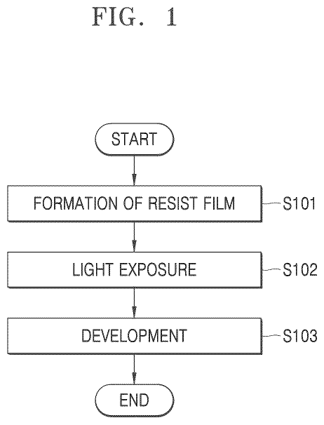

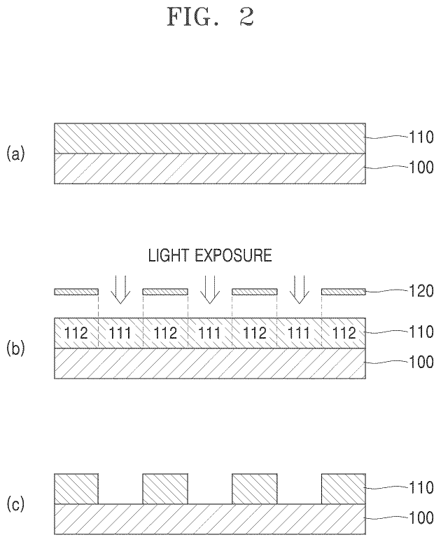

Hereinafter, a method of forming a pattern according to some embodiments will be described in more detail with reference to FIGS. 1 and 2. FIG. 1 is a flowchart illustrating the method forming a pattern method according to embodiments, and FIG. 2 shows side cross-sectional views illustrating the method of forming a pattern according to embodiments. Hereinafter, an example of the method of forming a pattern by using a positive photoresist composition will be described in detail, but one or more embodiments are not limited thereto.

Referring to FIG. 1, the method of forming a pattern may include operation S101 of applying a photoresist composition to form a photoresist film, operation S102 of exposing at least a portion of the resist film to high-energy rays, and operation S103 of developing the exposed photoresist film by using a developing solution. The example illustrated in the figures is based on a positive photoresist pattern; however, the examples are not limited thereto. Additionally, at least some examples, the steps may be omitted if necessary, and/or may be performed in a different order, and/or additional steps may be added.

First, a substrate 100 may be prepared. The substrate 100 may include, for example, a semiconductor substrate (such as a silicon substrate, a germanium substrate, and/or the like), glass, quartz, ceramic, a conductor (such as copper, silver, etc.), and/or the like. In some embodiments, the substrate 100 may include a Group III-V compound such as GaP, GaAs, GaSb, and/or the like.

A photoresist composition may be applied to a desired thickness on the substrate 100, specifically, through a coating method, to form a photoresist film 110. It at least some embodiments, heating may be performed to remove the organic solvent remaining in the photoresist film 110. As the coating method, spin coating, dipping, roller coating, and/or other general coating methods may be used. Among the coating methods, spin coating may be particularly used, and the viscosity, concentration, and/or spin speed of the photoresist composition may be adjusted to form the photoresist film 110 having a desired thickness. Specifically, the photoresist film 110 may have a thickness of about 10 nm to about 300 nm. More specifically, the photoresist film 110 may have a thickness of about 30 nm to about 200 nm.

A lower limit of a temperature of pre-bake may be 60° C. or more, specifically, 80° C. or more. In addition, an upper limit of the temperature of the pre-bake may be about 150° C. or less, specifically, about 140° C. or less. For example, the prebaking may be performed at a temperature between 60° C. to 150° C. A lower limit of a time of the pre-bake may be 5 seconds or more, specifically, 10 seconds or more. An upper limit of the time of the pre-bake may be 600 seconds or less, specifically, 300 seconds or less.

Before the applying of the photoresist composition onto the substrate 100, an etching target film (not shown) may be further formed on the substrate 100. The etching target film may refer to a layer on which an image is transferred from a photoresist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In at least one embodiment, an antireflection film may be further formed on the substrate 100 to maximize the efficiency of a photoresist. The antireflection film may be an organic or inorganic antireflection film.

In at least one embodiment, a protective film may be further provided on the photoresist film 110 to reduce the influence of alkaline impurities or the like included during a process. When immersion exposure is performed, for example, a protective film for immersion may also be provided on the photoresist film 110 to avoid direct contact between an immersion medium and the photoresist film 110.

Next, at least a portion of the photoresist film 110 may be exposed to high-energy rays. For example, high-energy rays passing through a mask 120 may be irradiated onto at least a portion of the resist film 110. For this reason, the photoresist film 110 may have an exposed portion 111 and an unexposed portion 112.

In some cases, the exposure may be performed by irradiating high-energy rays through a mask with a certain pattern using a liquid such as water as a medium. Examples of the high-energy rays may include electromagnetic waves such as UV rays, DUV rays, EUV rays (with a wavelength of 13.5 nm), X-rays, and 7-rays, and charged particle beams such as EBs and a rays, and/or the like. Irradiating the high-energy rays may be collectively referred to as “exposure” or “exposure to light”.

Examples of an exposure light source may include various light sources such as a light source that emits laser light in a UV region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less. In addition, when EBs are used as the high-energy rays, the integral dose may be 5,000 μC/cm² or less, specifically, 1,000 μC/cm² or less.

In addition, post-exposure bake (PEB) may be performed after the exposure. A lower limit of a temperature of the PEB may be 50° C. or more, specifically, 80° C. or more. An upper limit of the temperature of the PEB may be 180° C. or less, specifically, 130° C. or less. For example, the PEB may be performed at a temperature between 50° C. to 130° C. A lower limit of a time of the PEB may be 5 seconds or more, specifically, 10 seconds or more. An upper limit of the time of the PEB may be 600 seconds or less, specifically, 300 seconds or less.

Next, the exposed photoresist film 110 may be developed using a developing solution. The exposed portion 111 may be washed away by the developing solution, and the unexposed portion 112 may remain unwashed away by the developing solution.

Examples of the developing solution may include an alkaline developing solution and a developing solution including an organic solvent (hereinafter also referred to as “organic developing solution”). Examples of a developing method may include a dipping method, a puddle method, a spray method, a dynamic injection method, and/or the like. A developing temperature may be, for example, 5° C. or more and 60° C. or less, and a developing time may be, for example, 5 seconds or more and 300 seconds or less.

The alkaline developing solution may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethylammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkali developing solution may further include a surfactant.

A lower limit of a content of the alkaline compound in the alkali developing solution may be 0.1 wt % or more, specifically, 0.5 wt % or more, and more specifically, 1 wt % or more. In addition, an upper limit of the content of the alkaline compound in the alkaline developing solution may be 20 wt % or less, specifically, 10 wt % or less, and more specifically, 5 wt % or less.

After development, the photoresist pattern may be cleaned with ultrapure water, and then water remaining on the substrate 100 and the photoresist pattern may be removed.

Examples of the organic solvent included in the organic developing solution may include the same organic solvents as those exemplified in the part of <Organic solvent> of [Photoresist composition].

A lower limit of a content of the organic solvent in the organic developing solution may be 80 wt % or more, specifically, 90 wt % or more, more specifically, 95 wt % or more, or particularly, 99 wt % or more.

The organic developing solution may also include a surfactant. In addition, a trace amount of water may be included in the organic developing solution. Furthermore, during development, the development may be stopped by substituting the organic developing solution with a solvent that is a different type therefrom.

The photoresist pattern after the development may be further cleaned. Ultrapure water, a rinse solution, or the like may be used as a cleaning solution. A rinse solution is not particularly limited as long as the rinse solution does not dissolve a photoresist pattern, and a solution including a general organic solvent may be used. For example, the rinse solution may be an alcohol-based solvent or an ester-based solvent. After the cleaning, the rinse solution remaining on the substrate 100 and the photoresist pattern may be removed. In addition, when the ultrapure water is used, water remaining on the substrate 100 and the photoresist pattern may be removed.

In addition, developing solutions may be used singly and/or in a combination of two or more.

After the photoresist pattern is formed, a pattern interconnection substrate may be obtained through etching. The etching may be performed through a known method including dry etching (using a plasma gas), wet etching (using an alkaline solution, a cupric chloride solution, a ferric chloride solution, or the like), and/or the like.

After the photoresist pattern is formed, plating may be performed. The plating is not particularly limited, and examples thereof may include copper plating, solder plating, nickel plating, gold plating, and/or the like.

The photoresist pattern remaining after the etching may be removed through chemical and/or mechanical removal. For example, in at least one embodiment the photoresist pattern remaining after the etching may be peeled off with an organic solvent. One or more embodiments are not limited thereto, but examples of such an organic solvent may include propylene glycol monomethyl ether acetate (PGMEA), propylene glycol monomethyl ether (PGME), ethyl lactate (EL), and/or the like. A peeling method is not particularly limited, but examples thereof may include an immersion method, a spray method, and/or the like. In addition, the pattern interconnection substrate on which the photoresist pattern is formed may be a multilayer interconnection substrate or may have small-diameter through-holes.

In an embodiment, the pattern interconnection substrate may be formed through a method of forming a photoresist pattern, depositing a metal in a vacuum, and then melting the photoresist pattern with a solution, that is, a lift-off method.

The disclosure will be described in more detail using the following Examples and Comparative Examples, but the technical scope of the disclosure is not limited only to the following Examples.

### EXAMPLES

### Synthesis Example 1: Synthesis of Compound A

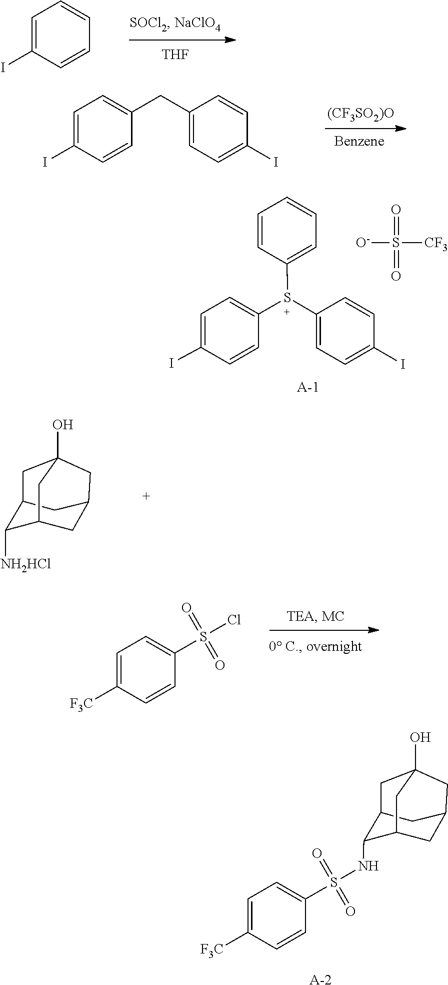

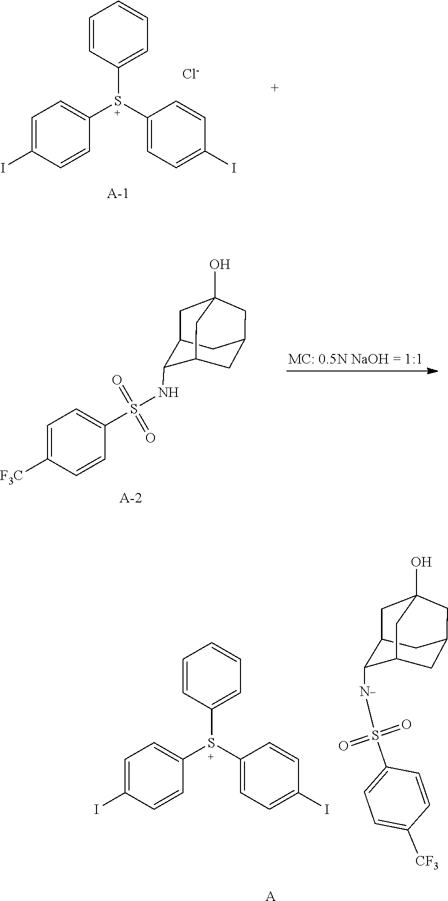

### Synthesis of Compound A-1

Compound A-1 was synthesized with reference to a synthesis method of Korean Patent Publication No. 10-2022-0074627.

4-iodobenzene (2.246 g, 11.01 mmol), thionyl chloride (0.655 g, 5.51 mmol), and sodium perchlorate (0.117 g, 0.96 mmol) were added to 12 mL of tetrahydrofuran and stirred for 3 hours. Thereafter, a reaction solvent was removed by distillation under reduced pressure, and an organic layer extracted and obtained with 30 mL of water and 30 mL of dichloromethane was dried with Na₂SO₄ and filtered. The residue obtained by depressurizing a filtrate obtained therefrom was separated and purified through column chromatography to obtain 4,4′-sulfinylbis(iodobenzene). A generated compound was confirmed through nuclear magnetic resonance (NMR).

¹H-NMR (300 MHz, CDCl₃): δ 7.05 (d, 4H), 7.42 (d, 4H)

After 4,4′-sulfinylbis(iodobenzene) (3.73 g, 8.20 mmol) was dissolved in 15 mL of benzene, trifluoromethanesulfonic anhydride (2.778 g, 9.85 mmol) was added dropwise and then stirred at room temperature for 1 hour. Thereafter, an organic layer extracted and obtained with 20 mL of water and 50 mL of ethyl acetate was cleaned with a saturated NaHCO₃ aqueous solution, dried with MgSO₄, and filtered. The residue obtained by depressurizing a filtrate obtained therefrom was separated and purified through silica gel column chromatography to obtain a Compound A-1 containing a cation (4.92 g, 90%). A generated compound was confirmed through NMR and liquid chromatography-mass spectrometry (LC-MS).

¹H-NMR (500 MHz, CD₂Cl₂): δ 7.37-7.40 (m, 4H), 7.65-7.67 (m, 2H), 7.73 (t, 2H), 7.81 (t, 1H), 8.06-8.08 (m, 4H), LC-MS m/z=515.8326 (cation).

### Synthesis of Compound A-2

2 g (1 eq) of trans-4-amino-1-adamantanol hydrochloride (manufactured by Sigma-Aldrich Co. LLC) was added to 30 ml of dichloromethane to obtain a solution, and then the obtained solution was stirred in an ice bath for 30 minutes. 1.73 ml of 4-trifluorobenzenesulfonyl chloride (manufactured by Sigma-Aldrich Co. LLC) was slowly added dropwise to the solution (1.1 equiv.), and then 2.76 ml (2.0 equiv.) of triethylamine was added thereto and allowed to react at room temperature for 12 hours. After the reaction, a reaction product was cleaned twice with a brine solution in a separatory funnel, and an organic layer was column-purified under conditions of Hex:EA=5:1 to obtain 0.83 g of Compound A-2. A generated compound was confirmed through NMR and liquid chromatography-mass spectrometry (LC-MS).

¹H-NMR (500 MHz, CD₂Cl₂): δ 7.99 (d, 2H), 7.805 (d, 2H), 4.92 (d, ¹H), 3.39 (d, ¹H), 2.08 (d, ¹H), 1.92 (d, 2H), 1.67 (m, 9H), 1.35 (m, 2H), LC-MS m/z=374.1729 (anion).

### Synthesis of Compound A

OTF compound (1 g, 1.58 mmol) and Cl Exchange Resin (3 g, Amberlight, Sigma-aldrich) were mixed with 10 mL of methanol and stirred for 2 hours. Afterwards, the filtrate obtained by filtration was distilled under reduced pressure to obtain Compound A-1 Cl (0.75 g, 92%).

Compound A-1 Cl (0.7 g, 1.27 mmol) and Compound A-2 (0.525 g, 1.4 mmol) were mixed with 10 ml of methylene chloride (MC) and 10 ml (1N) of a NaOH aqueous solution and then stirred for 2 hours. Thereafter, an organic layer was separated, dried with MgSO₄, and filtered to then remove a solvent under reduced pressure, and then a generated solid was cleaned with ether to obtain Compound A (1.03 g). A generated compound was confirmed through ¹H-NMR.

¹H-NMR (500 MHz, CD₂Cl₂): δ 8.03-8.01 (dd, 4H), 7.87 (m, 2H), 7.77 (m, 1H), 7.75 (m, 2H), 7.73 (m, 2H), 7.69-7.52 (m, 6H), 3.18 (m, 1H), 2.07 (m, 2H), 2.04 (br, 1H), 1.95 (m, 2H), 1.69 (s, 2H), 1.55 (m, 4H), 1.17 (m, 2H), 1.14 (m, 2H).

### Synthesis Example 2: Synthesis of Compound B

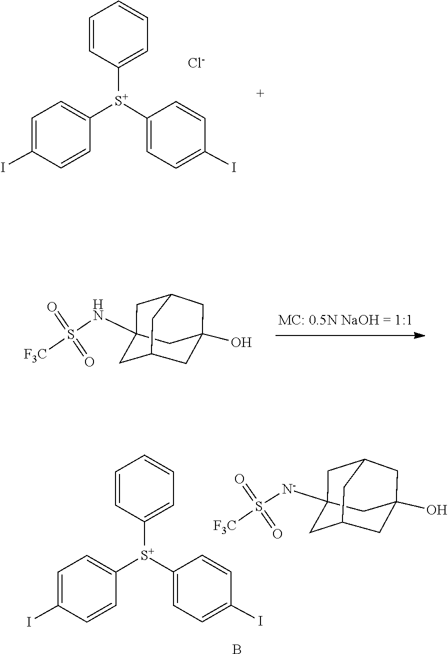

An anion was obtained in the same method as in the synthesis method of compound A-2, and then Compound B was obtained in the same manner as in the synthesis method of compound A, except that 3-amino-1-adamantanol (manufactured by TCI) was used instead of trans-4-amino-1-adamantanol hydrochloride (manufactured by TCI), and trifluoromethanesulfonic anhydride (manufactured by Sigma-Aldrich Co. LLC) was used instead of 4-(tert-butyl)benzenesulfonyl chloride. A generated compound was confirmed through ¹H-NMR.

¹H-NMR (500 MHz, CD₂Cl₂): δ 8.1 (dd, 4H), 7.85 (m, 1H), 7.75 (m, 4H), 7.52 (d, 4H), 2.32 (br, 1H), 2.03 (m, 2H), 1.75-1.55 (m, 10H), 1.39 (m, 2H).

### Synthesis Example 3: Synthesis of Compound C

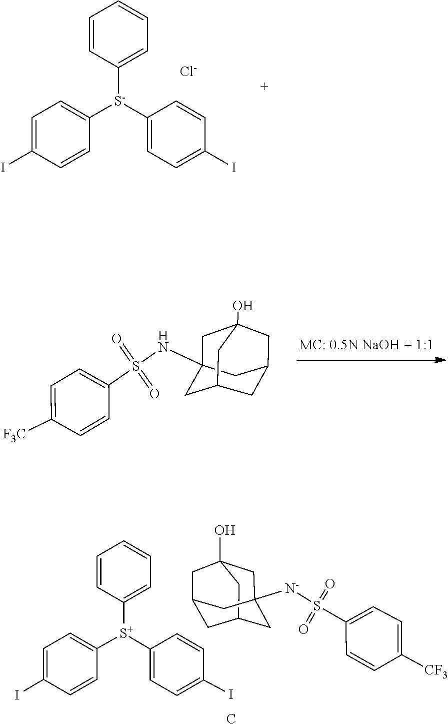

An anion was obtained in the same manner as in the synthesis method of compound A-2, and then Compound C was obtained in the same manner as in the synthesis method of compound A, except that 3-amino-1-adamantanol (manufactured by TCI) was used instead of trans-4-amino-1-adamantanol hydrochloride (manufactured by TCI). A generated compound was confirmed through ¹H-NMR.

¹H-NMR (500 MHz, CD₂Cl₂): δ 8.02 (dd, 4H), 7.91 (m, 2H), 7.73 (m, 3H), 7.68 (m, 2H), 7.66-7.50 (m, 6H), 2.30 (br, 1H), 2.02 (m, 2H), 1.65 (s, 2H), 1.56 (m, 4H), 1.46 (m, 4H), 1.35 (m, 2H).

### Synthesis Example 4: Synthesis of Compound D

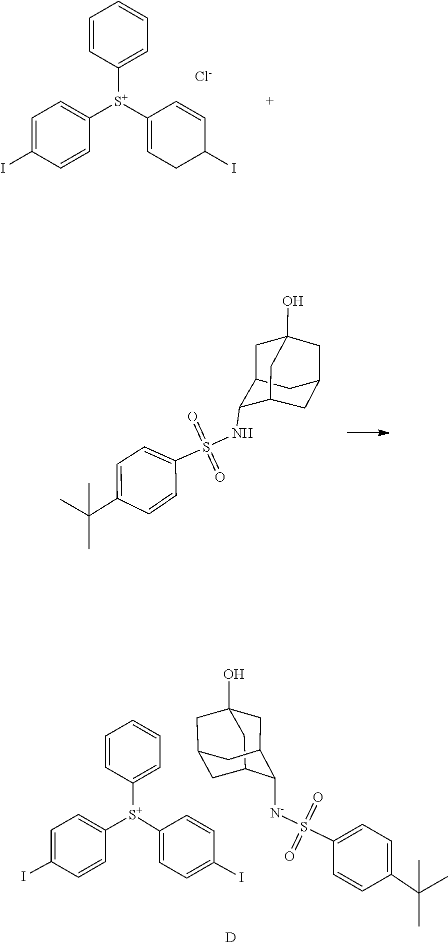

An anion was obtained in the same manner as in the synthesis method of Compound A-2, and then Compound D was obtained in the same manner as in the synthesis method of compound A, except that 4-(tert-butyl)benzenesulfonyl chloride (manufactured by Sigma-Aldrich Co. LLC) was used instead of trifluorobenzenesulfonyl chloride. A generated compound was confirmed through ¹H-NMR.

¹H-NMR (500 MHz, CD₂Cl₂): δ 8.01 (dd, 4H), 7.79 (m, 3H), 7.67 (m, 4H), 7.59 (m, 4H), 7.35 (m, 2H), 3.17 (s, 1H), 2.3 (br, 1H), 2.02 (m, 2H), 1.95 (m, 1H), 1.77 (s, 2H), 1.56 (m, 6H), 1.26 (s, 9H), 1.18 (m, 2H).

### Synthesis Example 5: Synthesis of Compound E

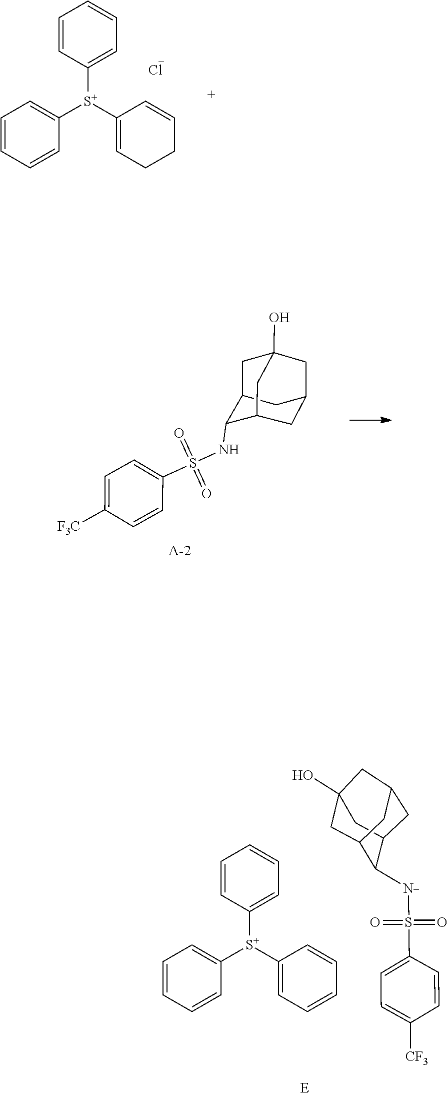

Compound E was obtained in the same manner as in the synthesis method of Compound A, except that triphenylsulfonium chloride (manufactured by TCI) was used instead of Compound A-1. A generated compound was confirmed through ¹H-NMR.

1H-NMR (500 MHz, CD2Cl2): δ 7.85 (m, 5H), 7.79 (m, 6H), 7.68 (m, 6H), 7.56 (m, 2H), 3.18 (s, 1H), 2.06-2.04 (m, 3H), 1.95 (m, 1H), 1.77 (s, 2H), 1.56 (m, 4H), 1.18 (m, 2H), 1.15 (m, 2H).

### Synthesis Example 6: Synthesis of Compound CE1

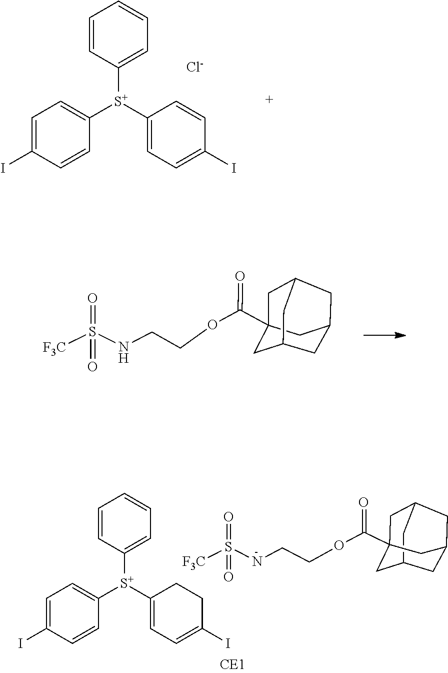 [SMILES: Ic1ccc([S+](c2ccccc2)c2ccc(I)cc2)cc1 ; [Cl-] ; O=C(OCCNS(=O)(=O)C(F)(F)F)C12CC3CC(CC(C3)C1)C2 ; IC1=CC=C([S+](c2ccccc2)c2ccc(I)cc2)CC1 ; O=C(OCCNS(=O)(=O)C(F)(F)F)C12CC3CC(CC(C3)C1)C2]

Compound CE1 was obtained in the same manner as in the synthesis method of Compound A, except that 2-((trifluoromethyl) sulfonamido)ethyl (3r,5r,7r)-adamantane-1-carboxylate was used instead of trans-4-amino-1-adamantanol hydrochloride (manufactured by TCI). Synthesis of 2-trifluoromethyl sulfonamido ethyl adamantane-1-carboxylate (2-((trifluoromethyl) sulfonamido)ethyl (3r,5r,7r)-adamantane-1-carboxylate) is disclosed in US Patent US20120214101. A generated compound was confirmed through ¹H-NMR.

¹H-NMR (500 MHz, CD₂Cl₂): δ 8.10 (d, 4H), 7.83 (m, 1H), 7.80-7.70 (m, 4H), 7.49 (m, 4H), 3.95 (t, 2H), 3.21 (t, 2H), 1.93 (s, 3H), 1.72 (s, 6H), 1.61 (m, 6H).

### Synthesis Example 7: Synthesis of Compound CE2

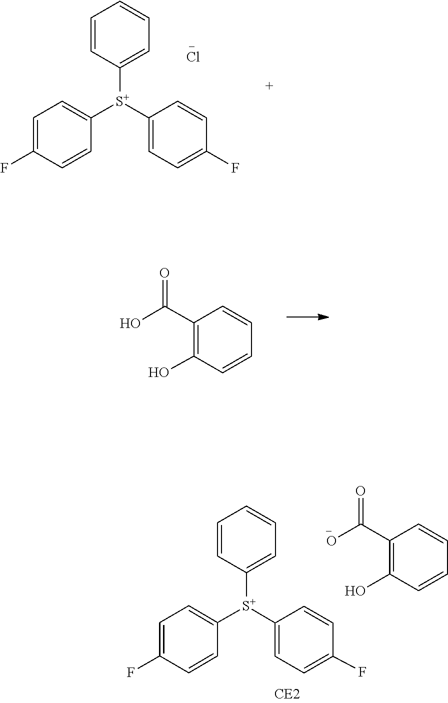

A compound of bis(4-fluorophenyl)phenylsulfonium chloride and a salicylic acid (manufactured by Sigma-Aldrich Co. LLC) were mixed with 10 ml of MC and 10 ml (1N) of a NaOH aqueous solution and then stirred for 2 hours. Thereafter, an organic layer was separated, dried with MgSO₄, and filtered to then remove a solvent under reduced pressure, and then a generated solid was cleaned with ether to obtain Compound CE2. A generated compound was confirmed through ¹H-NMR.

¹H-NMR (500 MHz, CD₂Cl₂): δ 15.5 (s, 1H), 7.83 (m, 4H), 7.70 (m, 2H), 7.65 (m, 4H), 7.41 (m, 4H), 7.15 (m, 1H), 6.7 (d, 1H), 6.65 (m, 1H).

### Evaluation Example 1. ADL Measurement

An ADL was measured using a method described in Macromolecules, 43(9)4275 (2010).

First, an HS/ECP polymer was dissolved at 1.6 wt % in a 7/3-wt/wt solution of PGME/PGMEA, and 0.048 mmol of triphenylsulfonium perfluoro-1-butanesufonate (TPS/PFBS) as a photoacid generator was added thereto to prepare a polymer solution including a photoacid generator. Separately, an HS/EAd polymer (poly(p-hydroxy styrene)-r-poly(ethyl adamantane)) was dissolved at 1.6 wt % in a 7/3 wt/wt solution of PGME/PGMEA, and then a solution including 0.032 mmol of a compound of Table 1 below was prepared.

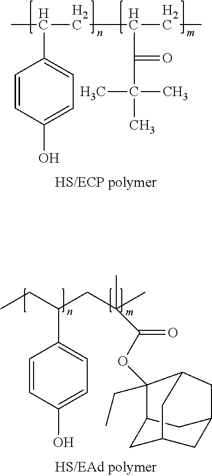

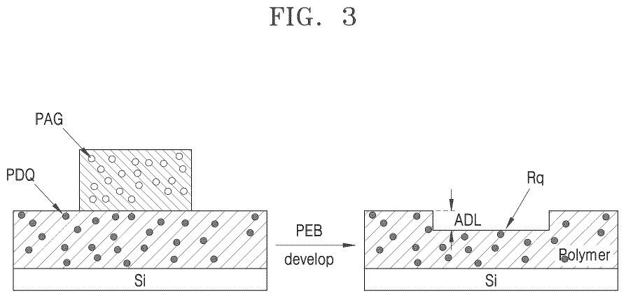

The polymer solution including the photoacid generator applied to a thickness of 100 nm on a polydimethylsiloxane (PDMS) substrate, which was treated to be hydrophilic with an ultraviolet ozone (UVO) cleaner, and exposed to DUV (248 nm) at 250 mJ/cm² to generate an acid from TPS-I2. Separately, an HS/ECP solution, which did not include a photoacid generator from which an acid was generated, was applied to a thickness of 100 nm on a Si wafer. Next, the PDMS substrate coated with a polymer thin film including a photoacid generator was placed on the Si wafer coated with a HS/ECP thin film, and pressure was applied to adsorb the PDMS substrate. Thereafter, when the PDMS substrate is separated, a polymer thin film including a photoacid generator is transferred onto the Si wafer coated with the HS/ECP thin film. Such a Si substrate was placed on a hot plate and subjected to a heat treatment process at a temperature of 90° C. for 60 seconds to allow an acid generated from an upper layer to diffuse into a lower HS/ECP thin film layer. After that, a developing process was performed with a 2.38 wt % TMAH aqueous solution (see FIG. 3).

The ADL could be confirmed by measuring and comparing a thickness of a first coated film and a thickness after the developing process on a finally obtained substrate. A relative ADL was shown by being normalized based on an ADL measurement value of Compound A.

TABLE 1

| | Compound No. | Relative ADL value |
|---|---|---|
| Example 1 | Compound A | 1.00 |
| Example 2 | Compound B | 0.94 |
| Example 3 | Compound C | 0.79 |
| Example 4 | Compound D | 0.57 |
| Example 5 | Compound E | 1.11 |
| Comparative Example 1 | Compound CE1 | 1.42 |
| Comparative Example 2 | Compound CE2 | 1.30 |
| Comparative Example 3 | Compound CE3 | 1.08 |
| Comparative Example 4 | Compound CE4 | 1.24 |

Compound CE1 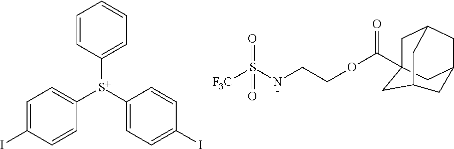 [SMILES: Ic1ccc([S+](c2ccccc2)c2ccc(I)cc2)cc1 ; O=C(OCCNS(=O)(=O)C(F)(F)F)C12CC3CC(CC(C3)C1)C2]
Compound CE2 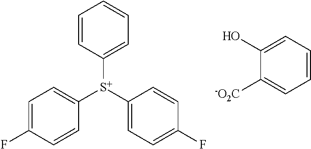
Compound CE3 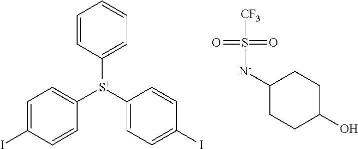 [SMILES: Ic1ccc([S+](c2ccccc2)c2ccc(I)cc2)cc1 ; O=S(=O)([N-]C1CCC(O)CC1)C(F)(F)F]
Compound CE4

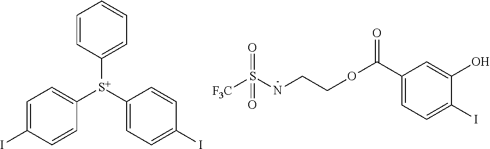 [SMILES: Ic1ccc([S+](c2ccccc2)c2ccc(I)cc2)cc1 ; O=C(OCCNS(=O)(=O)C(F)(F)F)c1ccc(I)c(O)c1]

Referring to Table 1, it can be seen that the ADL values of photoresist compositions of Examples 1 to 5 are smaller than those of photoresist compositions of Comparative Examples 1 to 4.

### Evaluation Example 2. Evaluation of Photoresist Performance

By using a method disclosed in Korean Patent Publication No. 10-2020-0163340, Z-factors of photoresist compositions including compounds in Table 2 were calculated. Results thereof are shown in Table 2 below:

$$Z - factor = {( resolution )}^{3} \times {( LWR )}^{2} \times ( Sensitivity ) \qquad Equation 1$$

In Equation 1, resolution denotes a critical dimension (CD) size (half pitch, nm), LWR denotes line width roughness (nm), and sensitivity is denoted by Eₒₚ(dose, mJ/cm²).

TABLE 2

| | | Reso- | | | |
|---|---|---|---|---|---|
| | | lution | Eₒₚ | LWR | Z-factor |
| | Compound | (nm) | (mJ/cm²) | (nm) | (mJ · nm³) |
| Example 6 | Compound A | 20 | 32.1 | 2.7 | 1.87 × 10⁻⁸ |
| Example 7 | Compound B | 20 | 30.3 | 2.93 | 1.87 × 10⁻⁸ |
| Comparative | Compound CE1 | 20 | 40.2 | 3.02 | 2.93 × 10⁻⁸ |
| Example 5 | | | | | |
| Comparative | Compound CE2 | 20 | 41.4 | 2.95 | 2.88 × 10⁻⁸ |
| Example 6 | | | | | |
| Comparative | Compound CE3 | 20 | 29.6 | 3.12 | 2.3 × 10⁻⁸ |
| Example 7 | | | | | |
| Comparative | Compound CE4 | 20 | 35.7 | 3.21 | 2.94 × 10⁻⁸ |
| Example 8 | | | | | |

Referring to Table 2, it can be confirmed that, in photoresist patterns to which photoresist films formed of photoresist compositions of Examples 6 and 7 are applied, the LWR and the Z-factor according to Eₒₚ are lower than those of photoresist patterns to which photoresist films formed of photoresist compositions of Comparative Examples 5 to 8 are applied.

Embodiments may provide a carboxylate capable of serving as a quencher having improved dispersibility and/or compatibility, and a photoresist composition including the same.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organic salt represented by Formula 1 below: 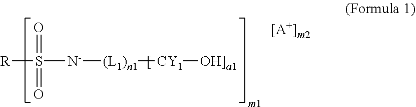
wherein, in Formula 1,
L₁ is a single bond or a (1+a1) valent linking group, wherein L₁ does not comprise a carbonyl group (C═O);
n1 is an integer from 1 to 5;
CY₁ is a cyclic C₁-C₂₀ divalent hydrocarbon group optionally comprising a heteroatom, and comprising two or more rings;
a1 is an integer from 1 to 5;
R is a linear, branched, or cyclic C₁-C₂₀ monovalent hydrocarbon group optionally comprising a heteroatom, a linear, branched, or cyclic C₁-C₂₀ divalent hydrocarbon group optionally comprising a heteroatom, or a linear, branched, or cyclic C₁-C₂₀ trivalent hydrocarbon group optionally comprising a heteroatom;
m1 and m2 are each an integer from 1 to 3; and
A⁺ is a counter cation.

2. The organic salt of claim 1, wherein L₁ is a single bond, a C₁-C₂₀ alkylene group that is unsubstituted or substituted with deuterium, a halogen, a C₁-C₂₀ alkyl group, or a combination thereof.

3. The organic salt of claim 1, wherein CY₁ is a C₃-C₂₀ cycloalkylene group, a C₁-C₂₀ heterocycloalkylene group, a C₆-C₂₀ arylene group, or a C₃-C₂₀ heteroarylene group, unsubstituted or substituted with deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or a combination thereof.

4. The organic salt of claim 1, wherein CY₁ is a cyclohexylene group, a cycloheptenylene group, a cyclooctenylene group, an adamantylene group, a norbornylene group, a tricyclodecaneylene group, or a tetracyclododecanylene group, unsubstituted or substituted with deuterium, a halogen, a hydroxyl group, a C₁-C₂₀ alkyl group, a C₃-C₂₀ cycloalkyl group, a C₆-C₂₀ aryl group, a C₃-C₂₀ heteroaryl group, or a combination thereof.

5. The organic salt of claim 1, wherein CY₁ is an adamantylene group, a norbornylene group, a tricyclodecaneylene group, or a tetracyclododecanylene group.

6. The organic salt of claim 1, wherein R comprises at least one fluorine atom.

7. The organic salt of claim 1, wherein R is a C₁-C₂₀ alkyl group, a C₃-C₂₀ cycloalkyl group, a C₁-C₂₀ heterocycloalkyl group, a C₆-C₂₀ aryl group, or a C₃-C₂₀ heteroaryl group, unsubstituted or substituted with deuterium, a halogen, a hydroxyl group, a C₁-C₂₀ alkyl group, a C₁-C₂₀ alkoxy group, a C₃-C₂₀ cycloalkyl group, a C₆-C₂₀ aryl group, a C₆-C₂₀ aryloxy group, a C₃-C₂₀ heteroaryl group, or a combination thereof.

8. The organic salt of claim 1, wherein a1 is 1 or 2.

9. The organic salt of claim 1, wherein
i) a1 is 1, and m1 and m2 are each 1; or
ii) a1 is 1, and m1 and m2 are each 2.

10. The organic salt of claim 1, wherein the organic salt represented by Formula 1 is represented by at least one of Formula 1-1 or Formula 1-2 below: 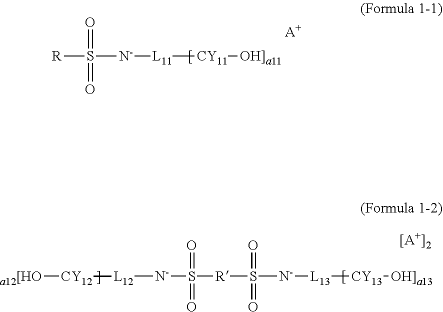
Wherein, in Formula 1-1 and Formula 1-2, L₁₁ is a single bond or a (1+a11) valent linking group, L₁₂ is a single bond or a (1+a12) valent linking group, and L₁₃ is a single bond or a (1+a13) valent linking group, wherein L₁₁ to L₁₃ each do not comprise a carbonyl group (C═O);
CY₁₁ to CY₁₃ are each independently a cyclic C₁-C₂₀ divalent hydrocarbon group optionally comprising a heteroatom and comprising two or more rings;
a11 to a13 are each independently an integer from 1 to 5;
R is a linear, branched, or cyclic C₁-C₂₀ monovalent hydrocarbon group optionally comprising a heteroatom; and
R′ is a linear, branched, or cyclic C₁-C₂₀ divalent hydrocarbon group optionally comprising a heteroatom.

11. The organic salt of claim 1, wherein A⁺ is a substituted or unsubstituted sulfonium cation, a substituted or unsubstituted iodonium cation, a substituted or unsubstituted selenium cation, a substituted or unsubstituted tellurium cation, a substituted or unsubstituted ammonium cation, or any combination thereof.

12. The organic salt of claim 1, wherein A⁺ is represented by one of Formulas 2-1 to 2-3 below: 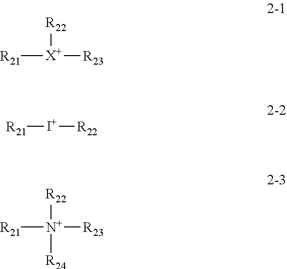
wherein, in Formulas 2-1 to 2-3, X⁺ is S⁺, Se⁺, or Te⁺,
R₂₁ to R₂₄ are each independently a linear, branched, or cyclic C₁-C₃₀ monovalent hydrocarbon group optionally comprising a heteroatom, and
adjacent two of R₂₁ to R₂₄ are optionally bonded to each other to form a ring.

13. The organic salt of claim 1, wherein A⁺ is represented by one of Formulas 2-11 to 2-13 below: 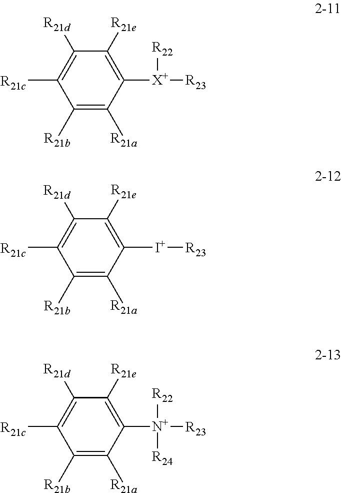
wherein, in Formulas 2-11 to 2-13, X⁺ is S⁺, Se⁺, or Te⁺,
R₂₁ₐ to R₂₁ₑ are each independently hydrogen, deuterium, a halogen, a cyano group, a hydroxy group, or a linear, branched, or cyclic C₁-C₂₀ monovalent hydrocarbon group optionally comprising a heteroatom,
R₂₂ to R₂₄ are each independently a linear, branched, or cyclic C₁-C₃₀ monovalent hydrocarbon group optionally comprising a hetero atom, and
adjacent two of R₂₁ₐ to R₂₁ₑ and R₂₂ to R₂₄ are optionally bonded to each other to form a ring.

14. The organic salt of claim 1, wherein A⁺ is selected from Group I below:

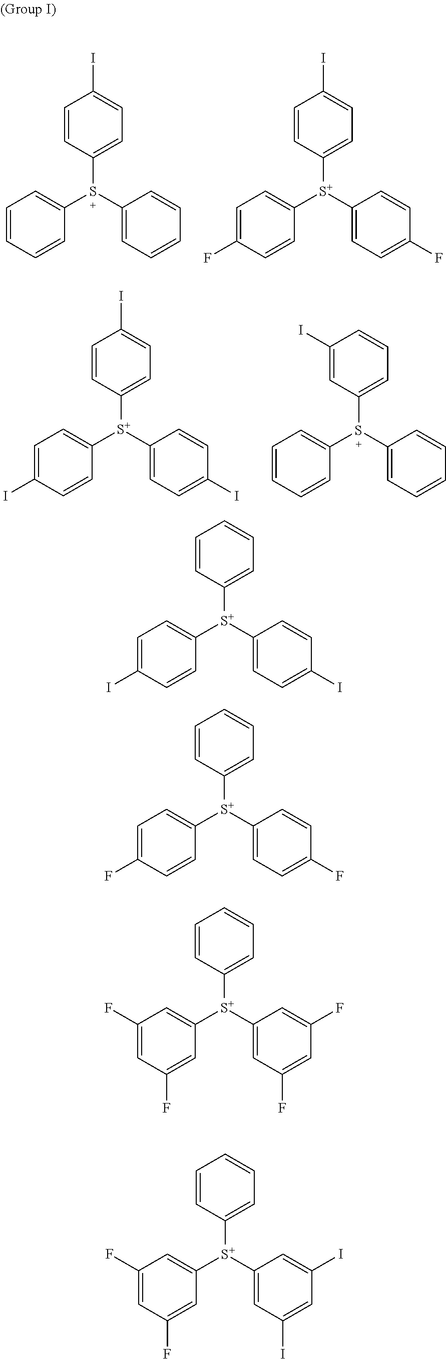

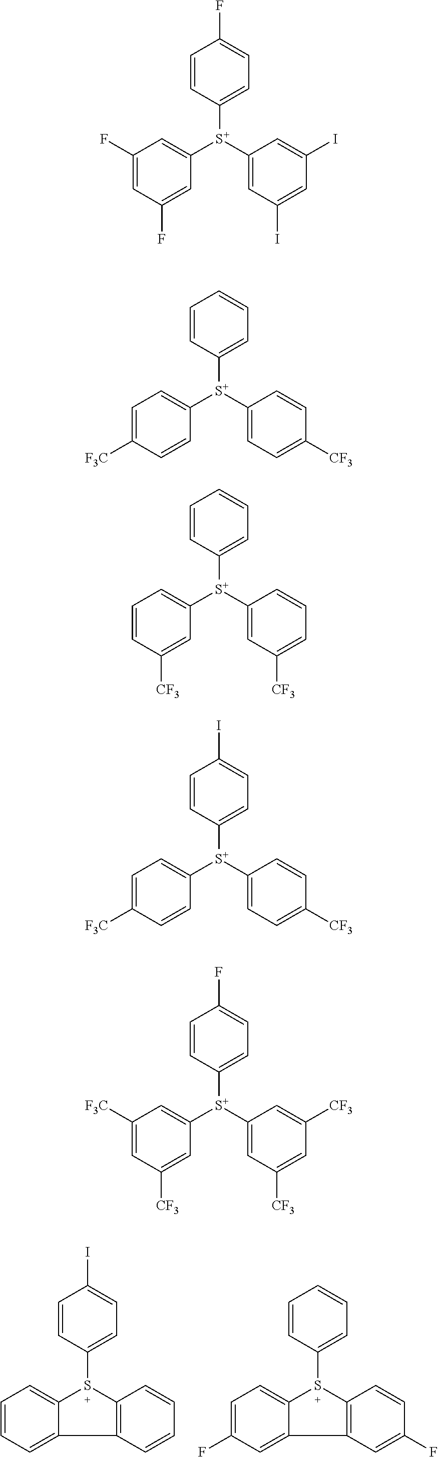

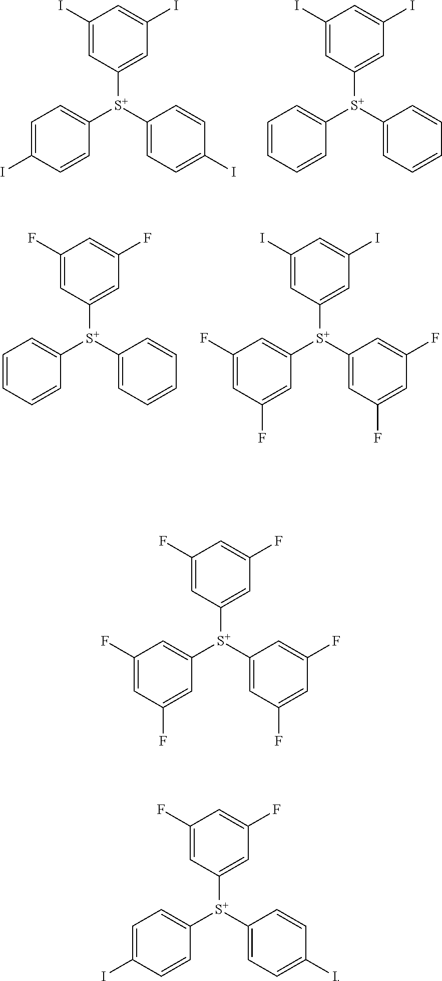 [SMILES: Ic1ccc([S+](c2ccc(I)cc2)c2cc(I)cc(I)c2)cc1 ; Ic1cc(I)cc([S+](c2ccccc2)c2ccccc2)c1 ; Fc1cc(F)cc([S+](c2ccccc2)c2ccccc2)c1 ; Fc1cc(F)cc([S+](c2cc(F)cc(F)c2)c2cc(I)cc(I)c2)c1 ; Fc1cc(F)cc([S+](c2cc(F)cc(F)c2)c2cc(F)cc(F)c2)c1 ; Fc1cc(F)cc([S+](c2ccc(I)cc2)c2ccc(I)cc2)c1]

15. The organic salt of claim 1, wherein the organic salt represented by Formula 1 is selected from Group II below: 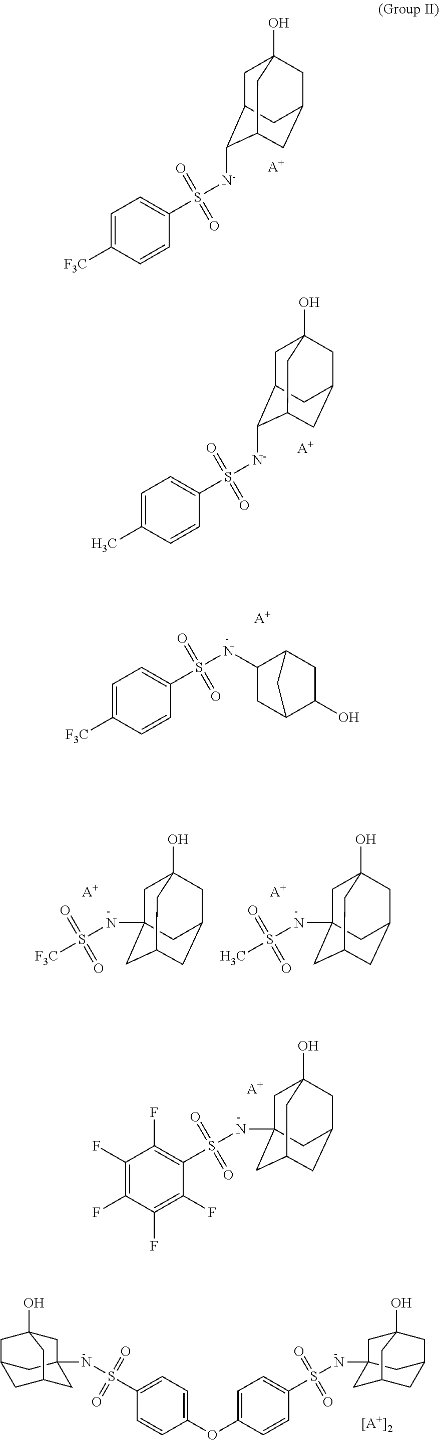 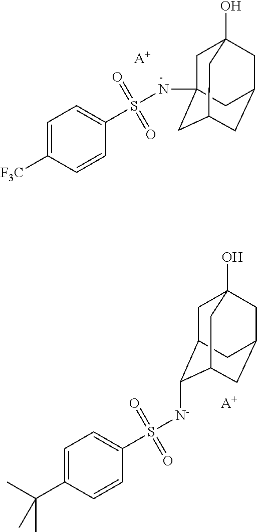
in Group II, A⁺ is as defined in claim 1.

16. A photoresist composition comprising:
the organic salt of claim 1;
an organic solvent; and
a base resin.

17. The photoresist composition of claim 16, wherein the organic salt is a photosensitive acid generation inhibitor.

18. The photoresist composition of claim 16, further comprising a photodegradable compound configured to generate an acid upon exposure to light.

19. A method of forming a pattern, the method comprising:
forming a photoresist film by applying the photoresist composition of claim 16 onto a substrate;
exposing at least a portion of the photoresist film to high-energy rays; and
developing the exposed photoresist film using a developing solution.

20. The method of claim 19, wherein the exposing includes irradiating at least one of ultraviolet (UV) rays, deep ultraviolet (DUV) rays, extreme ultraviolet (EUV) rays, or electron beams (EBs).
